(19) United States
(12) Patent Application Publication
(10) Pub. No.: US 2026/0161838 A1
(43) Pub. Date: Jun. 11, 2026

(54) SYSTEMS AND METHODS FOR AUTOMATED 3D MODELING AND DESIGN OF DECK STRUCTURES

(71) Applicant: Sean Preston Kurtz, Saline, MI (US)

(72) Inventor: Sean Preston Kurtz, Saline, MI (US)

(21) Appl. No.: 19/412,808

(22) Filed: Dec. 8, 2025

Related U.S. Application Data
(60) Provisional application No. 63/729,943, filed on Dec. 9, 2024.

(51) Int. Cl. G06F 30/13; G06T 17/00

(52) U.S. Cl. CPC G06F 30/13; G06T 17/00

(57) ABSTRACT

This disclosure is directed to systems, methods, apparatuses, and techniques that utilize automated three-dimensional modeling and automated engineering functionalities for deck structures and their support frameworks. A deck frame design engine can execute engineering tasks that determine structural components, dimensions, and configurations for deck framing plans to optimize the generation of code-compliant framing plans and optimize material usage based on user-specified parameters. Additionally, the outputs of the deck frame design engine can be received by a 3D modeling engine that creates interactive visualizations of proposed designs.

### CROSS-REFERENCE TO RELATED APPLICATIONS

This application claims the benefit of, and priority to, U.S. Provisional Patent Application No. 63/729,943 filed on Dec. 9, 2024. The content of the above-identified application is herein incorporated by reference in its entirety.

### TECHNICAL FIELD

This disclosure is related to systems, methods, and computer program products for designing and modeling deck structures and/or support frameworks. In certain embodiments, a deck design application can be executed to generate code-compliant deck framing plans and three-dimensional (3D) visualizations based on user-specified parameters.

### BACKGROUND

Deck structure design and construction are commonplace in residential and commercial building projects. Deck structures provide outdoor spaces that can enhance property value and functionality. Typical deck structures include a platform surface that is connected to an underlying support framework. These support frameworks include various structural elements that are utilized to elevate the platform surface above ground level and provide support to the platform surface, ensuring its stability and load-bearing capacity

Properly designing the support frameworks for deck structures is crucial for ensuring the overall safety and functionality of the deck structures. These frameworks should be carefully designed or engineered to maintain the integrity of the platform surface and meet specific load requirements, which may vary based on local building codes and intended usage. The support structures should be capable of withstanding both static loads from the deck's own weight and dynamic loads from occupants, furniture, and environmental factors such as wind or snow. Failing to properly design the support frameworks can have severe consequences, potentially leading to structural failure, which may result in serious injury to persons using the deck and/or located in its vicinity. Additionally, inadequate support design can cause significant damage to property, including the deck itself and any attached structures. Therefore, thorough consideration of structural engineering principles and adherence to relevant building codes are important in the design process of deck support frameworks.

Common design flaws that can lead to structural failure in deck structures include undersized or inadequate structural elements (e.g., posts, joists, beams, etc.), inadequate connections between structural elements, and improper spacing or positioning of structural elements. Additionally, failure to account for the impact of local environmental conditions, such as high winds or heavy snow loads, on load requirements also can compromise the integrity of the deck structures. In many cases, occurrences of these design flaws can be attributed to human error in engineering the deck structures, which may lead to overlooking necessary structural features and/or selecting inappropriate materials.

On the other hand, over-engineering of the support frameworks also is a problem. Over-engineering occurs when excessive materials or structural elements are unnecessarily incorporated into the support framework of the deck structures, which go beyond what is required for safe and efficient performance. This can lead to increased material costs, longer construction times, and additional labor expenses. Additionally, over-engineered deck structures may be unnecessarily heavy, potentially placing undue stress on the building to which they are attached or requiring more extensive foundation work.

The design and engineering of deck structures and their support frameworks are typically performed manually by experts such as architects, structural engineers, or experienced contractors. This manual approach relies heavily on the individual's knowledge, experience, and interpretation of building codes and structural principles. While expert input is valuable, manual design processes can be prone to human error as mentioned above. Additionally, manual calculations and plan drafting are often time-consuming, leading to longer project timelines and increased labor efforts and costs. The iterative nature of design revisions and code compliance checks can further extend the process. Moreover, as building codes evolve and become more complex, manually keeping up with the latest requirements can be challenging and may result in outdated or non-compliant designs.

Additionally, in many scenarios, experts are required to manually prepare detailed drawings and documentation for submission to local authorities as part of the building permit application process. This manual preparation of drawings can involve creating precise technical illustrations, specifying materials, and documenting compliance with local building codes and regulations. The process is often time-consuming and labor-intensive, requiring multiple revisions to address feedback from building officials or changes in design requirements. Manual drafting of permit drawings is also susceptible to human error, which can lead to delays in approval, costly revisions, or permit rejections. Furthermore, the need for experts to dedicate significant time to this process can increase overall project costs and potentially extend timelines for deck construction or renovation projects.

The background description provided herein is for the purpose of generally presenting context of the disclosure. The materials described in this section are not prior art to the claims in this application and are not admitted to be prior art, or suggestions of the prior art, by inclusion in this section.

### BRIEF DESCRIPTION OF DRAWINGS

Non-limiting and non-exhaustive examples are described with reference to the following figures. To facilitate further description of the embodiments, the following drawings are provided, in which like references are intended to refer to like or corresponding parts.

FIG. 1 is a diagram of an exemplary system according to certain embodiments.

FIG. 2 is a block diagram demonstrating exemplary features of a deck design application according to certain embodiments.

FIG. 3 is a block diagram illustrating exemplary specification parameters according to certain embodiments.

FIG. 4 is a block diagram illustrating exemplary deck frame design parameters according to certain embodiments.

FIG. 5 is a flow diagram illustrating an exemplary process flow for generating deck design results according to certain embodiments.

FIG. 6 is an exemplary method for generating a virtual 3D deck frame visualization according to certain embodiments.

FIG. 7A is an exemplary graphical user interface that may be displayed by a deck design application according to certain embodiments.

FIG. 7B is another exemplary graphical user interface that may be displayed by a deck design application according to certain embodiments.

FIG. 7C is another exemplary graphical user interface that may be displayed by a deck design application according to certain embodiments.

FIG. 8A is an exemplary virtual 3D deck frame visualization according to certain embodiments.

FIG. 8B is another exemplary virtual 3D deck frame visualization according to certain embodiments.

FIG. 8C is another exemplary virtual 3D deck frame visualization according to certain embodiments.

FIG. 8D is another exemplary virtual 3D deck frame visualization according to certain embodiments.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments described herein are, for example, capable of operation in sequences other than those illustrated or otherwise described herein.

The terms “left,” “right,” “front,” “rear,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the apparatus, methods, and/or articles of manufacture described herein are, for example, capable of operation in other orientations than those illustrated or otherwise described herein.

As used herein, “approximately” can, in some embodiments, mean within plus or minus ten percent of the stated value. In other embodiments, “approximately” can mean within plus or minus five percent of the stated value. In further embodiments, “approximately” can mean within plus or minus three percent of the stated value. In yet other embodiments, “approximately” can mean within plus or minus one percent of the stated value.

Certain data or functions may be described as “real-time,” “near real-time,” or “substantially real-time” within this disclosure. Any of these terms can refer to data or functions that are processed with a humanly imperceptible delay or minimal humanly perceptible delay. Alternatively, these terms can refer to data or functions that are processed within a specific time interval (e.g., in the order of milliseconds).

### DETAILED DESCRIPTION

The following description sets forth exemplary aspects of the present disclosure. It should be recognized, however, that such description is not intended as a limitation on the scope of the present disclosure. Rather, the description also encompasses combinations and modifications to those exemplary aspects described herein.

This disclosure relates to systems, methods, and computer program products that can overcome some or all of the aforementioned challenges and/or other problems associated with designing deck structures.

In certain embodiments, a deck design application is configured to automate and streamline the design of deck structures and/or their support frameworks. The deck design application can be configured to design and/or model code-compliant deck structures that are safe, durable, and optimized for material usage.

In certain embodiments, the deck design application can include a deck frame design engine that is configured to automate the design process for deck support frameworks. The deck frame design engine may utilize user-specified parameters to generate code-compliant framing plans for deck structures by selecting appropriate structural components for the support frameworks, determining optimal sizing and spacing of structural components, and/or accommodating load-bearing requirements. In some examples, the deck frame design engine can output a plurality of deck frame design parameters corresponding to quantities and specifications for joist members, post members, beam members, and/or other structural components to be included in deck support frameworks.

In certain embodiments, in generating proposed designs for deck support frameworks, the deck frame design engine also can optimize material usage by carefully balancing safety requirements with efficient resource allocation. For example, the deck frame design engine can incorporate programming logic that selects appropriate structural components and determines their optimal sizing and spacing, ensuring the support framework meets or exceeds relevant building codes and load-bearing requirements. At the same time, the engine avoids over-engineering by not incorporating excessive materials beyond what is necessary for structural integrity and code compliance, thereby minimizing waste and reducing overall material costs.

In certain embodiments, the deck design application also can include a 3D modeling engine that is configured to generate three-dimensional (3D) visualizations of support frameworks for the deck structures based, at least in part, on the framing plan produced by the deck frame design engine. In some examples, the 3D modeling engine may utilize the deck frame design parameters to create a virtual representation of a support framework, that depicts the support framework with accurate placement, sizing, and spacing of structural components, such as joist members, beam members, and post members. Additionally, the 3D modeling engine may render the 3D visualizations in an interactive manner that permits end-users to view the proposed designs from multiple angles, zoom in on specific details, and/or potentially make real-time modifications to the design.

The deck design application overcomes the aforementioned problems by automating and streamlining the design process for deck structures and/or their support frameworks. By utilizing a small set of user-specified parameters, the application generates code-compliant framing plans that are not only safe and durable but also optimized for material usage. The deck frame design engine incorporates programming logic that selects appropriate structural components, determines optimal sizing and spacing, and accommodates load-bearing requirements, thereby reducing the risk of human error in engineering calculations. Additionally, the application's 3D modeling capabilities facilitate the automated generation of visual representations for the structures. This automated approach significantly reduces the time and effort required for manual calculations and drafting, while ensuring adherence to the latest building codes and regulations. By balancing safety requirements with efficient resource allocation, the application minimizes both under-engineering and over-engineering, potentially leading to reduced materials and improved structural integrity.

The deck design application implements automated algorithms that accurately determine structural requirements based on user inputs and building codes, overcoming the technical problems associated with human, error-prone calculations and design compliance. These programmatic algorithms can incorporate engineering principles and up-to-date regulations to generate optimal structural specifications, thereby eliminating, or at least significantly reducing, the risk of under-engineering or over-engineering the support structures. Additionally, the deck design application provides a technical solution to the challenge of design visualization by offering the automated generation of interactive 3D models or other visualizations. These 3D visualizations may permit users to explore the proposed deck structure from multiple angles, zoom in on specific details, and/or incorporate real-time modifications. This advanced visualization capability enhances understanding of proposed designs, while also allowing for rapid, computer-aided generation of drawings or visualizations to be submitted with permitting processes.

Additionally, the disclosed system introduces a fully automated, code-compliant, and deterministic deck-framing design engine that produces a complete structural framing layout, material list, and 3D structural model using only a minimal set of user inputs. Existing CAD (computer-assisted design) tools, span calculators, or rule-based design assistants require extensive manual drafting, manual placement of components, and/or manual engineering judgment. The disclosed system can overcome these and other challenges by incorporating various features described in this disclosure, including features that:
a. automatically determine all structural framing parameters (including joist size, joist spacing, span length, cantilever limits, beam size, beam quantity, beam spacing, post size, post quantity, and board lengths) strictly from a small number of user-provided specification parameters;
b. integrate building-code constraints directly into algorithmic rules such that all generated framing configurations are automatically validated for structural and regulatory compliance without requiring a human designer;
c. generate multiple optimized framing configurations for the same user inputs, enabling the user to select between designs that vary by structural efficiency, material usage, cost, or layout;
d. automatically generate a 3D structural model using the computed structural parameters, where joists, beams, and posts are instantiated, sized, and placed in coordinate-accurate positions without user intervention; and/or
e. transform high-level deck specifications into a full build-ready framing plan, including exact component counts, material dimensions, and an editable 3D visualization.

No existing design software known to the inventor provides this combination of: (1) minimal inputs, (2) automatic code-compliant engineering, (3) multi-option optimization, (4) direct integration of engineering outputs into specially-configured 3D modeling functions, and (5) automatic structural 3D model assembly generation. This combination of deterministic engineering logic plus automated 3D model construction yields a technical improvement not found in prior tools or systems.

The embodiments described in this disclosure can be combined in various ways. Any aspect or feature that is described for one embodiment can be incorporated to any other embodiment mentioned in this disclosure. Moreover, any of the embodiments described herein may be hardware-based, may be software-based, or, preferably, may comprise a mixture of both hardware and software elements. Thus, while the description herein may describe certain embodiments, features, or components as being implemented in software or hardware, it should be recognized that any embodiment, feature and/or component referenced in this disclosure can be implemented in hardware and/or software.

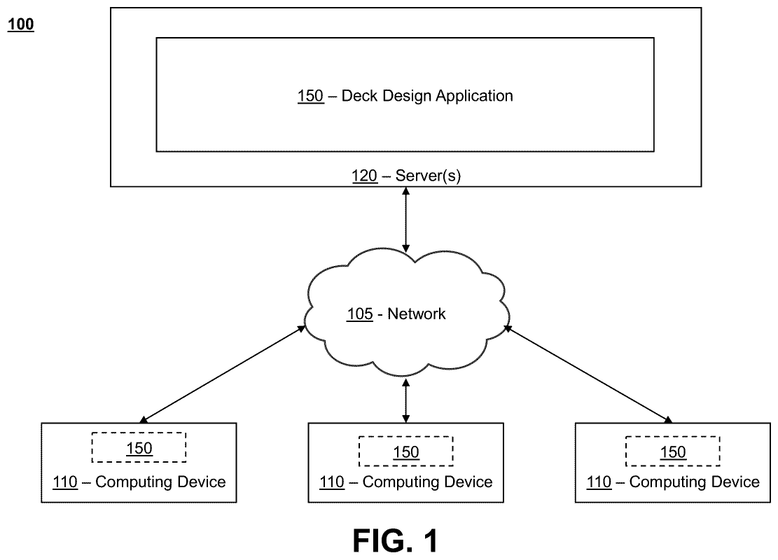

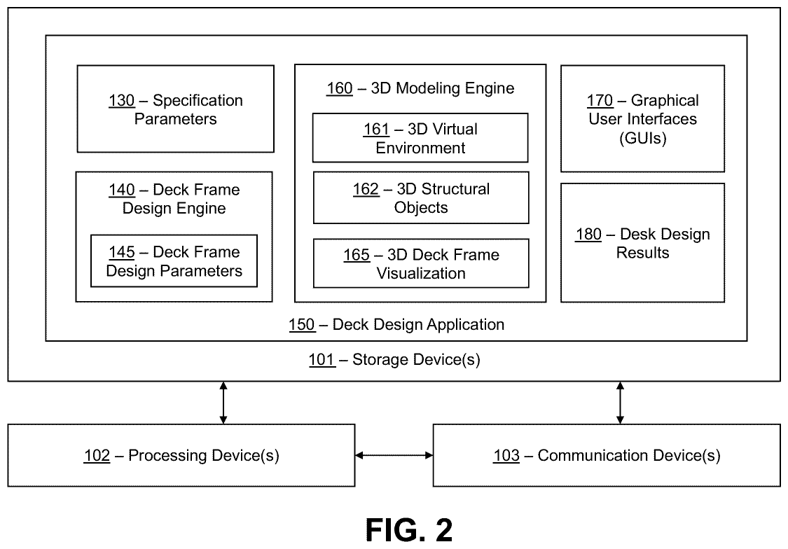

FIG. 1 is a diagram of an exemplary system 100 illustrating a deck design application 150 within a network environment in accordance with certain embodiments. FIG. 2 is a block diagram illustrating exemplary components, features, and/or functions associated with a deck design application 150 in accordance with certain embodiments. FIGS. 1 and 2 are described jointly below.

The system 100 comprises one or more computing devices 110 and one or more servers 120 that are in communication over a network 105. A deck design application 150 can be stored on, and executed by, the one or more servers 120, the one or more computing devices 110, or a combination thereof. The network 105 may represent any type of communication network, e.g., such as one that comprises a local area network (e.g., a Wi-Fi network), a personal area network (e.g., a Bluetooth network), a wide area network, an intranet, the Internet, a cellular network, a television network, a satellite communication network, and/or other types of networks.

All the components illustrated in FIG. 1, including the computing devices 110, servers 120, and deck design application 150 can be configured to communicate directly with each other and/or over the network 105 via wired or wireless communication links, or a combination of the two. Each of the computing devices 110, servers 120, and deck design application 150 can include one or more storage devices 101, one or more processing devices 102, and/or one or more communication devices 103.

The one or more storage devices 101 may include (i) non-volatile memory, such as, for example, read only memory (ROM) and/or (ii) volatile memory, such as, for example, random access memory (RAM). The non-volatile memory may be removable and/or non-removable non-volatile memory. RAM may include dynamic RAM (DRAM), static RAM (SRAM), etc. Further, ROM may include mask-programmed ROM, programmable ROM (PROM), one-time programmable ROM (OTP), erasable programmable read-only memory (EPROM), electrically erasable programmable ROM (EEPROM) (e.g., electrically alterable ROM (EAROM) and/or flash memory), etc. In certain embodiments, the one or more storage devices 101 include physical, non-transitory mediums. The one or more computer storage 101 devices can store instructions for implementing any of the functionalities associated with the deck design application 150.

The one or more processing devices 102 may include one or more central processing units (CPUs), one or more microprocessors, one or more microcontrollers, one or more controllers, one or more complex instruction set computing (CISC) microprocessors, one or more reduced instruction set computing (RISC) microprocessors, one or more very long instruction word (VLIW) microprocessors, one or more graphics processor units (GPU), one or more digital signal processors, one or more application specific integrated circuits (ASICs), and/or any other type of processor or processing circuit capable of performing desired functions. The one or more processing devices 102 can be configured to execute any computer program instructions that are stored or included on the one or more storage devices 101 including, but not limited to, instructions associated with executing the functionalities of the deck design application 150.

Each of the one or more communication devices 103 can include wired and wireless communication devices and/or interfaces that enable communications using wired and/or wireless communication techniques. Wired and/or wireless communication can be implemented using any one or combination of wired and/or wireless communication network topologies (e.g., ring, line, tree, bus, mesh, star, daisy chain, hybrid, etc.) and/or protocols (e.g., personal area network (PAN) protocol(s), local area network (LAN) protocol(s), wide area network (WAN) protocol(s), cellular network protocol(s), powerline network protocol(s), etc.). Exemplary PAN protocol(s) can comprise Bluetooth, Zigbee, Wireless Universal Serial Bus (USB), Z-Wave, etc. Exemplary LAN and/or WAN protocol(s) can comprise Institute of Electrical and Electronic Engineers (IEEE) 802.3 (also known as Ethernet), IEEE 802.11 (also known as WiFi), etc. Exemplary wireless cellular network protocol(s) can comprise Global System for Mobile Communications (GSM), General Packet Radio Service (GPRS), Code Division Multiple Access (CDMA), Evolution-Data Optimized (EV-DO), Enhanced Data Rates for GSM Evolution (EDGE), Universal Mobile Telecommunications System (UMTS), Digital Enhanced Cordless Telecommunications (DECT), Digital AMPS (IS-136/Time Division Multiple Access (TDMA)), Integrated Digital Enhanced Network (iDEN), Evolved High-Speed Packet Access (HSPA+), Long-Term Evolution (LTE), WiMAX, etc. The specific communication software and/or hardware can depend on the network topologies and/or protocols implemented. In certain embodiments, exemplary communication hardware can comprise wired communication hardware including, but not limited to, one or more data buses, one or more universal serial buses (USBs), one or more networking cables (e.g., one or more coaxial cables, optical fiber cables, twisted pair cables, and/or other cables). Further exemplary communication hardware can comprise wireless communication hardware including, for example, one or more radio transceivers, one or more infrared transceivers, etc. Additional exemplary communication hardware can comprise one or more networking components (e.g., modulator-demodulator components, gateway components, etc.). In certain embodiments, the one or more communication devices can include one or more transceiver devices, each of which includes a transmitter and a receiver for communicating wirelessly. The one or more communication devices 103 also can include one or more wired ports (e.g., Ethernet ports, USB ports, auxiliary ports, etc.) and related cables and wires (e.g., Ethernet cables, USB cables, auxiliary wires, etc.).

In certain embodiments, the one or more communication devices 103 additionally, or alternatively, can include one or more modem devices, one or more router devices, one or more access points, and/or one or more mobile hot spots. For example, modem devices may enable the computing devices 110, server(s) 120, and/or deck design application 150 to be connected to the Internet and/or other network. The modem devices can permit bi-directional communication between the Internet (and/or other network) and the computing devices 110, server(s) 120, and/or deck design application 150. In certain embodiments, one or more router devices and/or access points may enable the computing devices 110, server(s) 120, and/or deck design application 150 to be connected to a LAN and/or other more other networks. In certain embodiments, one or more mobile hot spots may be configured to establish a LAN (e.g., a Wi-Fi network) that is linked to another network (e.g., a cellular network). The mobile hot spot may enable the computing devices 110, server(s) 120, and/or deck design application 150 to access the Internet and/or other networks.

In certain embodiments, the computing devices 110 may represent mobile devices (e.g., smart phones, personal digital assistants, cell phones, tablet devices, vehicular computing devices, wearable devices, or any other device that is mobile in nature), desktop computers, laptop computers, gaming consoles and/or other types of devices. The one or more servers 120 may generally represent any type of computing device, including any of the computing devices 110 mentioned above. The one or more servers 120 also can comprise one or more mainframe computing devices, one or more virtual servers, one or more application servers, and/or one or more cloud-based servers. In some embodiments, the one or more servers 120 can be configured to execute web servers and can communicate with the computing devices 110 and/or other devices over the network 105 (e.g., over the Internet).

As mentioned above, some or all of the computing devices 110 may represent mobile electronic devices in certain embodiments. Generally speaking, the mobile electronic devices can include any type of electronic device that is portable and/or transportable in nature. In some cases, a mobile electronic device can refer to a portable electronic device (e.g., an electronic device easily conveyable by hand by a person of average size) with the capability to present audio and/or visual data (e.g., text, images, videos, music, etc.). For example, a mobile electronic device can comprise at least one of a cellular telephone (e.g., a smartphone), a personal digital assistant, a handheld digital computer device (e.g., a tablet personal computer device), a digital media player, a wearable device, and/or another portable computer device with the capability to present audio and/or visual data (e.g., images, videos, music, etc.). Thus, in many examples, a mobile electronic device can comprise a volume and/or weight sufficiently small as to permit the mobile electronic device to be easily conveyable by hand. For examples, in some embodiments, a mobile electronic device can occupy a volume of less than or equal to approximately 1790 cubic centimeters, 2434 cubic centimeters, 2876 cubic centimeters, 4056 cubic centimeters, and/or 5752 cubic centimeters. Further, in these embodiments, a mobile electronic device can weigh less than or equal to 15.6 Newtons, 17.8 Newtons, 22.3 Newtons, 31.2 Newtons, and/or 44.5 Newtons.

Exemplary mobile electronic devices can comprise (i) an iPod®, iPhone®, iTouch®, iPad®, and/or similar products offered by Apple Inc. of Cupertino, California, United States of America; (ii) a Blackberry® or similar product by Research in Motion (RIM) of Waterloo, Ontario, Canada; (iii) a Lumia® or similar product by the Nokia Corporation of Keilaniemi, Espoo, Finland, and/or (iv) a Galaxy® or similar product by the Samsung Group of Samsung Town, Seoul, South Korea. Further, in the same or different embodiments, a mobile electronic device can comprise an electronic device configured to implement one or more of (i) the iOS® or iPhone® operating system by Apple Inc. of Cupertino, California, United States of America, (ii) the Blackberry® operating system by Research In Motion (RIM) of Waterloo, Ontario, Canada, (iii) the Palm® operating system by Palm, Inc. of Sunnyvale, California, United States, (iv) the Android® operating system developed by the Open Handset Alliance, (v) the Windows Mobile™ operating system by Microsoft Corp. of Redmond, Washington, United States of America, or (vi) the Symbian™ operating system by Nokia Corp. of Keilaniemi, Espoo, Finland.

The mobile electronic devices can additionally, or alternatively, include wearable devices (e.g., wearable user computer devices) as mentioned above. Generally speaking, wearable devices can generally include any type of electronic device that is capable of be mounted to, worn by, and/or fixed to an individual. For example, in some cases, the wearable devices sometimes can be worn under or over clothing, and/or integrated with the clothing and/or other accessories (e.g., hats, eyeglasses, wristbands, watches, shoes, gloves, etc.). In some cases, wearable devices can be directly mounted or attached to individuals (e.g., the individuals' head, wrist, arms, legs, or neck regions). The wearable devices can comprise a head mountable wearable user computer device (e.g., one or more head mountable displays, one or more eyeglasses, one or more contact lenses, one or more retinal displays, etc.) and/or a limb mountable wearable user computer device (e.g., a smart watch). In some configurations, the wearable devices can be configured to present audio and/or visual data (e.g., text, images, videos, audio, music, etc.) and/or to receive inputs from individuals (e.g., via one or more input devices such as touchscreens, switches, buttons, etc.). The mobile electronic devices can include additional types of devices other than those explicitly mentioned herein.

In certain embodiments, the deck design application 150 can be stored on, and executed by, the one or more servers 120. Additionally, or alternatively, the deck design application 150 can be stored on, and executed by, the one or more computing devices 110. Thus, in some embodiments, the deck design application 150 can be stored as a server application executed by one or more servers 120 and, in other embodiments, can be stored as a local application executed by a computing device 110.

Additionally, in some embodiments, the deck design application 150 can be implemented as a combination of a front-end application (e.g., which is stored on a computing device 110) and a back-end application (e.g., which is stored on one or more servers 120). All functionalities of the deck design application 150 described herein can be executed by the front-end application, the back-end application, or a combination of both.

In certain embodiments, the deck design application 150 can be integrated with (or can communicate with) various applications including, but not limited to, structural design applications, engineering applications, architectural applications, building permit applications, and/or other applications that are stored on a computing device 110 and/or server 120.

In certain embodiments, end-users may access the deck design application 150 to design and/or model support frameworks for deck structures and/or other portions of the deck structures. In some examples, an end-user may provide certain specification parameters to the deck design application 150 corresponding to a desired deck structure, such as the desired length, width, and height of the deck structure and/or other parameters relating to joist spacing or sizes and cantilever preferences. In response to receiving the specification parameters, the deck design application 150 may execute a programmatic process that automates the design of support frameworks for deck structures and/or other portions of the deck structures. In doing so, the deck design application 150 may generate a framing plan for the deck structure that is not only structurally sound and code-compliant, but which also optimizes the usage of materials for constructing the deck structure according to the framing plan. Additionally, in certain embodiments, the deck design application 150 may execute, or communicate with, a three-dimensional (3D) modeling engine which creates a 3D visualization of the framing plan and/or design for the deck structures. The deck design application 150 can transmit or display deck design results to the end-user, which may include the framing plan details, 3D visualization, material list, structural component dimensions, and/or other data associated with the designing the deck structure or its support framework.

The system configuration illustrated in FIG. 1 is provided as an example to demonstrate an environment in which embodiments described herein can be deployed. Numerous modifications and variations to the disclosed embodiments are possible, and the techniques described herein can be implemented in many other contexts and environments.

FIG. 2 is a block diagram illustrating exemplary components of the deck design application 150 according to certain embodiments. While certain portions of this disclosure may describe these components as being separate or distinct, the functionalities associated with these components can be combined in various ways. Thus, any function described for a given component can be integrated with, or performed by, any other component of the deck design application 150.

The deck design application 150 can include a deck frame design engine 140, a 3D modeling engine 160, and one or more graphical user interfaces (GUIs) 170. The deck design application 150 also can store specification parameters 130 and deck design results 180.

In certain embodiments, the deck design application 150 executes a programmatic process for designing a support framework that is initiated in response to the deck design application 150 receiving a set of specification parameters 130. In some examples, an end-user may be presented with one or more GUIs 170 that enable the specification parameters 130 to be input to the deck design application 150. In other examples, the specification parameters 130 may be received via an API of the design application 150 (e.g., from an external system or application interfaced with the deck design application 150).

Various types of specification parameters 130 can be provided to inform the deck design application 150 about the deck structure being constructed or planned, and the deck design application 150 can utilize the specification parameters 130 to design the support framework for the deck structure. In some examples, the specification parameters 130 may correspond to the dimensions or features of a desired deck platform to be supported and/or elevated by the support framework. In other examples, the specification parameters 130 also may include design preferences corresponding to the support framework.

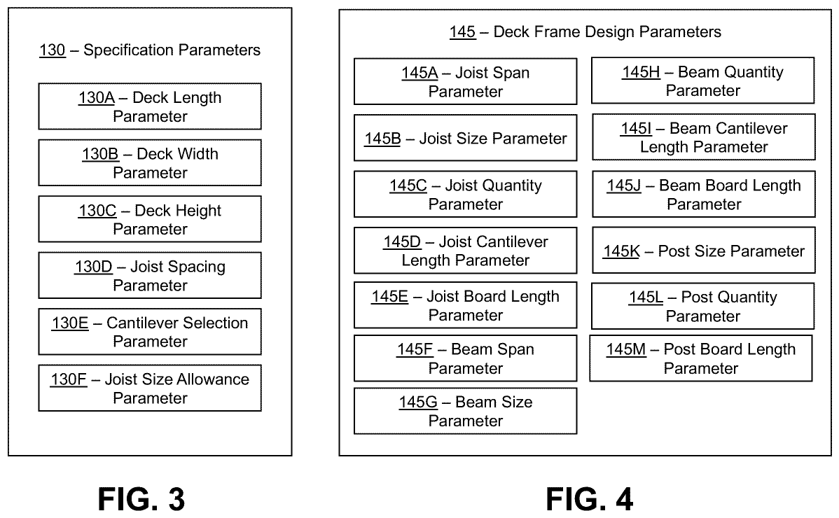

FIG. 3 is a block diagram illustrating exemplary specification parameters 130 that may be received or collected by the deck design application 150 in accordance with certain embodiments. The specification parameters 130 can include some or all of the parameters mentioned below.
1) Deck length parameter 130A: This parameter indicates a length of a deck platform to be supported and/or elevated by the support framework (e.g., in feet and/or other measurements).
2) Deck width parameter 130B: This parameter indicates a width of the deck platform to be supported and/or elevated by the support framework (e.g., in feet and/or other measurements);
3) Deck height parameter 130C: This parameter indicates a height of the deck platform to be supported and/or elevated by the support framework (e.g., in feet and/or other measurements). In some examples, the height of the deck platform may correspond to a distance between a ground surface upon which the support framework rests and a top surface of the deck platform. In certain embodiments, the deck design application 150 may impose a limitation on the maximum value of this parameter (e.g., requiring this value to be set to approximately fourteen feet or less in order to be compliant with certain code specifications).
4) Joist spacing parameter 130D: This parameter indicates a distance or spacing between joist members to be incorporated into the support framework. The distance or spacing may vary based on load requirements. In certain embodiments, the deck design application 150 may include two preset options for defining this parameter (e.g., a first option for twelve-inch joist spacing and a second option for sixteen-inch joist spacing).
5) Cantilever selection parameter 130E: A cantilever deck refers to a deck structure that is designed with an overhang of the deck platform and joists beyond an underlying support beam(s). This parameter allows the end-user to specify whether or not the support framework to be designed by the deck design application 150 is for a cantilever deck.
6) Joist size allowance parameter 130F: This parameter indicates whether certain sized joists may be utilized for the design of the support framework. For example, this parameter may enable an end-user to specify whether or not 2 inch×12 inch joists may be utilized.

The exemplary specification parameters 130 described above are not intended to be limiting. In certain embodiments, additional specification parameters 130 may be utilized and/or a portion of the specification parameters 130 may be omitted. Any specification parameters 130 collected or received by the deck design application 150 may be stored in memory (e.g., on storage device 101).

Returning to FIG. 2, the specification parameters 130 may be provided to, or accessed by, the deck frame design engine 140 of the deck design application 150. The deck frame design engine 140 can be configured to execute programming logic that, inter alia, utilizes the specification parameters 130 to select or identify the structural components (e.g., such as joist elements, post elements, and/or beam elements) for assembling the support framework for the desired deck structure, including the sizes, dimensions, and/or quantities of each structural component. The programming logic executed by the deck frame design engine 140 also may determine the positioning of, or connections among, the structural components.

In certain embodiments, the programming logic executed by the deck frame design engine 140 can be configured or adapted to generate or derive appropriate structural component design parameters in a manner that is compliant with one or more building code specifications (e.g., International Building Code 2015 (IBC) Tables R507.5 and R507.6, or other suitable specifications). For example, in designing the support framework, the programming logic may ensure that sufficient quantities of posts, beams, and/or joists are selected for supporting a platform surface based on code specifications. In another example, the programming logic may ensure that the joists are only permitted to cantilever to a certain extent based on code specifications. In further examples, the programming logic may ensure that structural components are sufficiently spaced based on code specifications.

In some examples, the programming logic can be applied to generate or determine a set of deck frame design parameters 145 according to the following:
a. Joist Span: Maximum allowable span for the joists based on deck dimensions and a building code specification (e.g., IBC Table R507.5).
b. Joist Size: Selection from 2×6, 2×8, 2×10, or 2×12 inches, based on span requirements.
c. Number of Joists: Total number of joists required for the framing plan.
d. Joist Cantilever Length: Length of cantilever for the joists, if applicable.
e. Joist Board Length: Adjusted for a maximum board length of 20 feet to accommodate larger decks.
f. Beam Span: Maximum allowable span for beams, calculated using IBC Table R507.6.
g. Beam Size: Selection from 2-2×6, 2-2×8, 2-2×10, or 2-2×12.
h. Number of Beams: Total beams required.
i. Beam Cantilever Length: Length of cantilever for beams, if applicable.
j. Beam Board Length: Adjusted for a maximum board length of 20 feet to accommodate larger decks.
k. Post Size: Determined as 4×4 or 6×6 inches based on load requirements.
l. Number of Posts: Total posts required for the framing plan.
m. Post Board Length: Length of the posts based on deck height.

Additionally, or alternatively, in certain embodiments, the programming logic executed by the deck frame design engine 140 can be designed to enforce some or all of the design rules or parameters described below.

With regard to the design of the deck joists, the programming logic executed by the deck frame design engine 140 may be adapted to implement rules for enforcing or implementing some or all of the specifications illustrated in Table 1 below.

TABLE 1

| | | SPACING OF DECK | | | SPACING OF DECK | | |
|---|---|---|---|---|---|---|---|
| SPECIES/ | | JOISTS WITH NO | | | JOISTS WITH | | |
| MATE- | SIZE | CANTILEVER (inches) | | | CANTILEVERS (inches) | | |
| RIALS | (inches) | 12 | 16 | 24 | 12 | 16 | 24 |
| Southern | 2 × 6 | 9-11 | 9-0 | 7-7 | 6-8 | 6-8 | 6-8 |
| pine | 2 × 8 | 13-1 | 11-10 | 9-8 | 10-1 | 10-1 | 9-8 |
| | 2 × 10 | 16-2 | 14-0 | 11-5 | 14-6 | 14-0 | 11-5 |
| | 2 × 12 | 18-0 | 16-6 | 13-6 | 18-0 | 16-6 | 13-6 |
| Douglas | 2 × 6 | 9-6 | 8-8 | 7-2 | 6-3 | 6-3 | 6-3 |
| fir-larch | 2 × 8 | 12-6 | 11-1 | 9-1 | 9-5 | 9-5 | 9-1 |
| hem-fir | 2 × 10 | 15-8 | 13-7 | 11-1 | 13-7 | 13-7 | 11-1 |
| spruce- | 2 × 12 | 18-0 | 15-9 | 12-10 | 18-0 | 15-9 | 12-10 |
| pine-fir | | | | | | | |
| Redwood, | 2 × 6 | 8-10 | 8-0 | 7-0 | 5-7 | 5-7 | 5-7 |
| western | 2 × 8 | 11-8 | 10-7 | 8-8 | 8-6 | 8-6 | 8-6 |
| cedars, | 2 × 10 | 14-11 | 13-0 | 10-7 | 12-3 | 12-3 | 10-7 |
| ponderosa | 2 × 12 | 17-5 | 15-1 | 12-4 | 16-5 | 15-1 | 12-4 |
| pine, | | | | | | | |
| red pine | | | | | | | |

Additionally, the joist design logic may enforce additional rules that encompass some or all of the following principles:
a. The deck joists are permitted to cantilever not greater than one-fourth of the actual, adjacent joist span.
b. Joist ends and bearing locations shall be provided with lateral restraint to prevent rotation. Where lateral restraint is provided by joist hangers or blocking between joists, their depth shall equal not less than 60 percent of the joist depth. Where lateral restraint is provided by rim joists, they shall be secured to the end of each joist with not less than (3) 10d (3-inch×0.128-inch) nails or (3) No. 10×3-inch (76 mm) long wood screws.

With regard to the design of the deck beams, the programming logic executed by the deck frame design engine 140 may be adapted to implement rules for enforcing or implementing maximum allowable spans according to some or all of the specifications illustrated in Table 2 below.

TABLE 2

| | | DECK JOIST SPAN LESS THAN | | | | | | |
|---|---|---|---|---|---|---|---|---|
| | | OR EQUAL TO: (feet) | | | | | | |
| SPECIES | SIZE | 6 | 8 | 10 | 12 | 14 | 16 | 18 |
| Southern | 2 - 2 × 6 | 6-11 | 5-11 | 5-4 | 4-10 | 4-6 | 4-3 | 4-0 |
| pine | 2 - 2 × 8 | 8-9 | 7-7 | 6-9 | 6-2 | 5-9 | 5-4 | 5-0 |
| | 2 - 2 × 10 | 10-4 | 9-0 | 8-0 | 7-4 | 6-9 | 6-4 | 6-0 |
| | 2 - 2 × 12 | 12-2 | 10-7 | 9-5 | 8-7 | 8-0 | 7-6 | 7-0 |
| | 3 - 2 × 6 | 8-2 | 7-5 | 6-8 | 6-1 | 5-8 | 5-3 | 5-0 |
| | 3 - 2 × 8 | 10-10 | 9-6 | 8-6 | 7-9 | 7-2 | 6-8 | 6-4 |
| | 3 - 2 × 10 | 13-0 | 11-3 | 10-0 | 9-2 | 8-6 | 7-11 | 7-6 |
| | 3 - 2 × 12 | 15-3 | 13-3 | 11-10 | 10-9 | 10-0 | 9-4 | 8-10 |
| Douglas | 3 × 6 | 5-5 | 4-8 | 4-2 | 3-10 | 3-6 | 3-1 | 2-9 |
| fir-larch, | or 2 - | | | | | | | |
| hem-fir, | 2 × 6 | | | | | | | |
| spruce- | 3 × 8 | 6-10 | 5-11 | 5-4 | 4-10 | 4-6 | 4-1 | 3-8 |
| pine-fir, | or 2 - | | | | | | | |
| redwood, | 2 × 8 | | | | | | | |
| western | 3 × 10 | 8-4 | 7-3 | 6-6 | 5-11 | 5-6 | 5-1 | 4-8 |
| cedars, | or 2 - | | | | | | | |
| ponderosa | 2 × 10 | | | | | | | |
| pine, | 3 × 12 | 9-8 | 8-5 | 7-6 | 6-10 | 6-4 | 5-11 | 5-7 |
| red pine | or 2 - | | | | | | | |
| | 2 × 12 | | | | | | | |
| | 4 × 6 | 6-5 | 5-6 | 4-11 | 4-6 | 4-2 | 3-11 | 3-8 |
| | 4 × 8 | 8-5 | 7-3 | 6-6 | 5-11 | 5-6 | 5-2 | 4-10 |
| | 4 × 10 | 9-11 | 8-7 | 7-8 | 7-0 | 6-6 | 6-1 | 5-8 |
| | 4 × 12 | 11-5 | 9-11 | 8-10 | 8-1 | 7-6 | 7-0 | 6-7 |
| | 3 - 2 × 6 | 7-4 | 6-8 | 6-0 | 5-6 | 5-1 | 4-9 | 4-6 |
| | 3 - 2 × 8 | 9-8 | 8-6 | 7-7 | 6-11 | 6-5 | 6-0 | 5-8 |
| | 3 - 2 × 10 | 12-0 | 10-5 | 9-4 | 8-6 | 7-10 | 7-4 | 6-11 |
| | 3 - 2 × 12 | 13-11 | 12-1 | 10-9 | 9-10 | 9-1 | 8-6 | 8-1 |

Additionally, the joist design logic may enforce additional rules for some or all of the following:
a. Beam plies shall be fastened with two rows of 10d (3-inch×0.128-inch) nails minimum at 16 inches (406 mm) on center along each edge.
b. Beams shall be permitted to cantilever at each end up to one-fourth of the actual beam span.
c. Splices of multi-span beams shall be located at interior post locations.

In certain embodiments, the programming logic executed by the deck frame design engine 140 can be configured to generate or determine a plurality of deck frame design parameters 145 based on the specification parameters 130 received by the deck design application. The deck frame design parameters 145 can define various aspects of the support framework that is being designed for the deck structure. Amongst other things, the deck frame design parameters 145 may indicate the sizes, dimensions, and/or quantities of each structural component to be incorporated into the support framework.

FIG. 4 is a block diagram illustrating exemplary deck frame design parameters 145 that may be generated or determined by the deck frame design engine 140 in accordance with certain embodiments. The deck frame design parameters 145 can include some or all of the parameters mentioned below.

Joist span parameter 145A: This parameter indicates the maximum allowable span for the joists based on deck dimensions.

Joist size parameter 145B: This parameter indicates the size of joists to be used based on span requirements. In some cases, the size may be selected from one of the following: 2 inch×6 inch, 2 inch×8 inch, 2 inch×10 inch, or 2 inch×12 inch.

Joist quantity parameter 145C: This parameter indicates the total number of joists to be included in the framing plan for the support framework.

Joist cantilever length parameter 145D: This parameter indicates the length of the cantilever for the joists (if applicable, where cantilever design is being used for the deck structure).

Joist board length parameter 145E: This parameter indicates the length of joist boards. In certain embodiments, this parameter may be adjusted for a maximum board length of 20 feet to accommodate larger decks.

Beam span parameter 145F: This parameter indicates the maximum allowable span for beams.

Beam size parameter 145G: This parameter indicates the size of beams to be used. In some embodiments, the size may be selected from one of the following: 2 inch×6 inch, 2 inch×8 inch, 2 inch×10 inch, or 2 inch×12 inch.

Beam quantity parameter 145H: This parameter indicates the total number of beams included in the framing plan for the support framework.

Beam cantilever length parameter 145I: This parameter indicates the length of the cantilever for beams, if applicable.

Beam board length parameter 145J: This parameter indicates the length of beam boards. In certain embodiments, this parameter may be adjusted for a maximum board length of 20 feet to accommodate larger decks.

Post size parameter 145K: This parameter indicates the size of posts to be used. In some cases, the parameter may be determined as 4 inches×4 inches or 6 inches×6 inches based on load requirements.

Post quantity parameter 145L: This parameter indicates the total number of posts to be included in the framing plan for the support framework.

Post board length parameter 145M: This parameter indicates the length of the posts. In certain embodiments, this parameter may be based on a deck height for the deck structure.

The exemplary deck frame design parameters 145 described above are not intended to be limiting. In certain embodiments, additional deck frame design parameters 145 may be utilized and/or a portion of the deck frame design parameters 145 may be omitted. Any deck frame design parameters 145 generated by the deck design application 150 may be stored in memory (e.g., storage device 101).

Returning to FIG. 2, the deck frame design parameters 145 and/or specification parameters 130 may be provided to, or accessed by, the 3D modeling engine 160 of the deck design application 150. The 3D modeling engine 160 can be configured to execute programming logic that, inter alia, utilizes some or all of the parameters to generate a 3D deck frame visualization 165 corresponding to the design of the support framework.

In certain embodiments, the 3D modeling engine 160 may be configured to generate a 3D virtual environment that 161 operates in a Cartesian coordinate system (X, Y, and Z axes), allowing for precise placement and/or manipulation of objects in a virtual space. Within this environment, the engine may insert various 3D structural objects 162 corresponding to deck structure components, such as joist objects, beam objects, post objects, and other elements of the support framework. These objects may be dynamically adjusted in size, quantity, and position based on the deck frame design parameters 145 output by the deck frame design engine 140. Additionally, the objects may be arranged in precise locations (e.g., defined by X, Y, and Z coordinates) relative to each other to assemble support framework and/or other portions of the deck structure. The 3D modeling engine 160 may include rendering capabilities to create realistic visualizations 165 of the deck structure. Additionally, the 3D deck frame visualizations 165 may be configured with interactive features, enabling users to view the 3D model from multiple angles and, in some cases, enabling end-users to make real-time modifications to the design.

Upon completing the design of a support framework (and, in some cases, other portions of the deck structure), the deck design application 150 may transmit deck design results 180 to an end-user that initiated the design request. The deck design results 180 may include any or all of the following:
1) Material specifications for each structural component of the support framework, including sizes, dimensions, and quantities of joists, beams, posts, and other elements.
2) A comprehensive bill of materials listing all required components for constructing the deck structure.
3) Some or all of the deck frame design parameters 145 generated by the deck frame design engine 140.
4) One or more 3D deck frame visualizations 165 corresponding to the proposed support framework and/or deck structure, each of which may be interactive and allow users to view the design from multiple angles.
5) A detailed framing plan outlining the structural components of the deck support framework.
6) Estimated material costs based on current market prices for the specified components.
7) Assembly instructions or guidelines for constructing the deck structure according to the generated design.
8) Compliance documentation demonstrating adherence to relevant building codes and standards.
9) Alternative design options, if applicable, presenting different configurations or material choices that meet the specified requirements.
10) Exportable files of the deck structure design, which may be compatible with CAD software or other design tools.
11) A summary of load-bearing calculations used to determine the structural integrity of the design.
12) Recommendations for additional features (e.g., such as railings, stairs, or built-in seating, if applicable to the design).
13) Estimated construction timeline based on the complexity of the design and typical build times.
14) Suggestions for finishes, treatments, and/or maintenance procedures to ensure longevity of the deck structure.
15) Any warnings or special considerations related to the specific design, such as terrain adaptations or climate-specific recommendations.

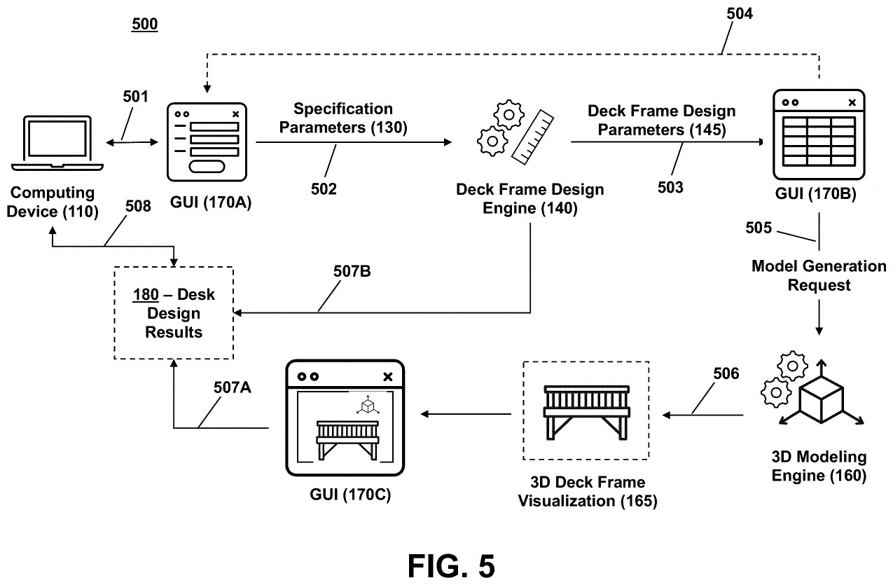

FIG. 5 illustrates an exemplary process flow 500 that may be executed by the deck design application 150 and/or systems described herein according to certain embodiments.

Process flow 500 is merely exemplary and is not limited to the embodiments presented herein. Process flow 500 can be employed in many different embodiments or examples not specifically depicted or described herein. In some embodiments, the steps of process flow 500 can be performed in the order presented. In other embodiments, the steps of process flow 500 can be performed in any suitable order. In still other embodiments, one or more of the steps of process flow 500 can be combined or skipped. In many embodiments, system 100 and/or deck design application 150 can be configured to perform process flow 500 and/or one or more of the steps of process flow 500. In these or other embodiments, one or more of the steps of process flow 500 can be implemented as one or more computer instructions configured to run at one or more processing devices 102 and configured to be stored at one or more non-transitory computer storage devices 101. Such non-transitory memory storage devices 101 can be part of a computer system, such as system 100, computing device 110, and/or server 120.

As explained throughout this disclosure, the deck design application 150 can be configured to create code-compliant deck framing plans and dimension specifications with high precision and speed. In some embodiments, the deck design application may be implemented as a Python-based platform, web-based platform, Saas (software-as-a-service), or other similar type of platform. In some examples, the deck design application 150 can generate a complete framing plan by processing six user inputs and delivering a detailed output of desk design results 180, which indicates material specifications, a listing of construction materials, a listing of structural component quantities, and/or a 3D rendering of the proposed structure. Additionally, in many examples, the deck design application can be programmed to leverage one or more building code specifications to ensure compliance with industry standards while also executing balancing logic that optimizes material usage.

In step 501, a computing device 110 operated by an end-user accesses a first graphic user interface (GUI) 170A via the deck design application 150. In certain embodiments, the first GUI 170A may be accessed via a mobile application and/or web browser installed on the computing device 110 (e.g., which may represent a smartphone, mobile device, desktop computer, tablet, etc.).

When the user initially accesses the deck design application 150, the user may be presented with an option to initiate the creation of a new deck framing plan and, upon selecting this option, the first GUI 170A may be presented to the end-user. The first GUI 170A can include a specially designed input form that facilitates the collection of specification parameters 130 corresponding to the design of a new deck structure and/or its corresponding support framework. The first GUI 170A can be configured to collect any of the specification parameters 130 described in this disclosure. In some examples, the first GUI 170A can be configured to collect the following six specification parameters 130: a deck length parameter 130A, a deck width parameter 130B, a deck height parameter 130C, a joist spacing parameter 130D, a cantilever selection parameter 130E, and a joist size allowance parameter 130F.

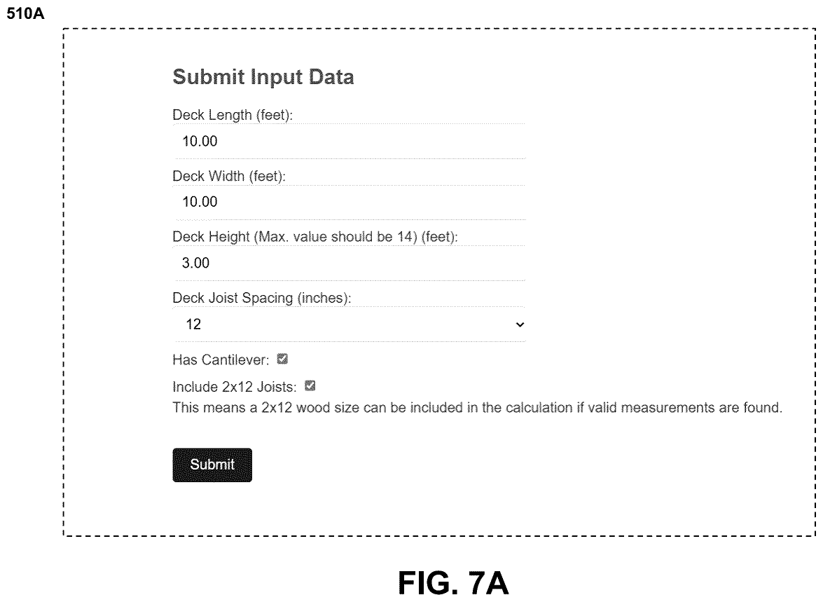

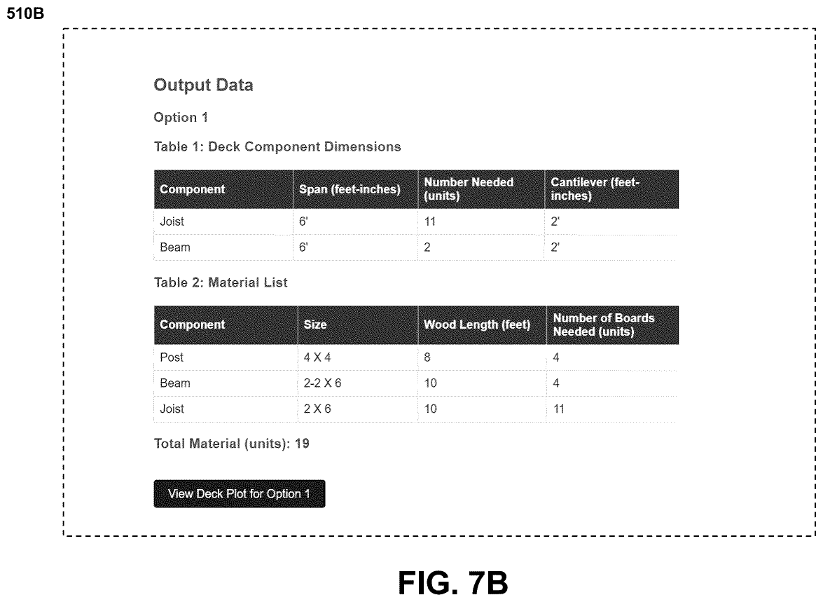

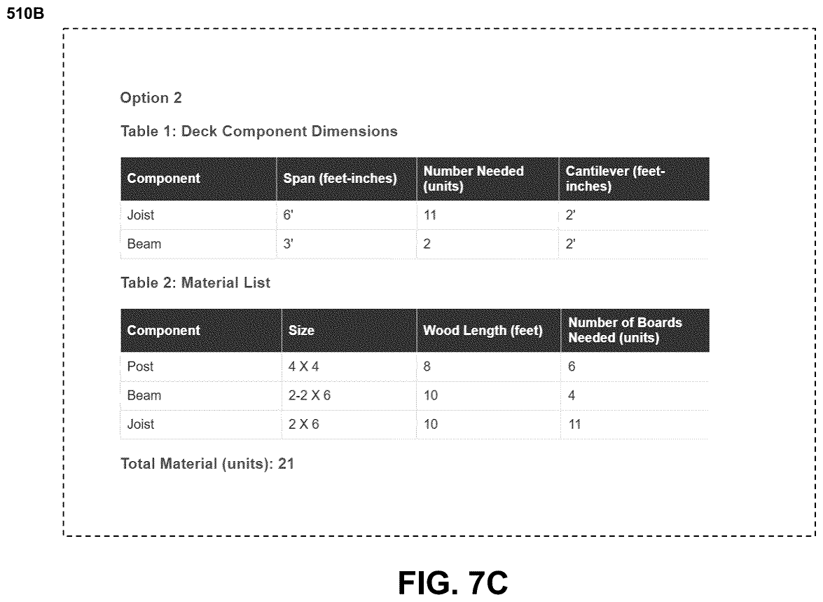

FIG. 7A is one example of the first GUI 170A that may be utilized to collect the six specification parameters 130 mentioned above for the deck framing plan that is being created. Using only these six inputs, the deck design application 150 can design a comprehensive deck framing plan that includes material specifications, a construction material listing, a listing of structural component quantities, and/or a 3D rendering of the proposed structure. As such, the deck design application 150 significantly streamlines the end-to-end deck design workflow by reducing manual calculations, automating code-compliance checks, and instantly generating optimized framing plans and interactive 3D visualizations. Collectively, this drastically shortens design time, minimizes material waste and over-engineering, lowers project costs, and facilitates faster permit approvals through clear, standards-based documentation.

In some alternative embodiments, the specification parameters 130 can be received via an application programming interface (API) instead of, or in addition to, a user interface. For example, the API can enable the deck design application 150 to communicate with various types of programs, applications, or systems (e.g., engineering applications, architectural applications, etc.), which can initiate requests to create deck framing plans and provide corresponding specification parameters 130 each of the plans. Amongst other things, embodiments that include API functionality can permit the technology associated with the deck design application 150 to be integrated into automated design systems.

In step 502, the specification parameters 130 collected via the first GUI 170A are received as an input to the deck frame design engine 140.

Upon receiving the specification parameters 130, the deck frame design engine 140 can execute programmatic logic to derive a code-compliant support framework tailored to the specified deck geometry and design preferences specified by the specification parameters 130. In some examples, the deck frame design engine 140 can analyze the deck length, deck width, and deck height values to establish candidate joist spans and beam spans, apply joist spacing and cantilever selections to constrain allowable overhangs and clearances, and/or evaluate joist size allowances to determine viable member sizes. Additionally, in some embodiments, the specially designed programmatic logic of the deck frame design engine 140 can be configured to compute maximum allowable spans, select species-appropriate and size-appropriate structural members, and/or enforce cantilever limits, lateral restraint requirements, and fastening provisions in alignment with one or more building code specifications. Based on these and/or other determinations, the deck frame design engine 140 can generate a plurality of deck frame design parameters 145.

The deck frame design parameters 145 generated by the deck frame design engine 140 can include any of those mentioned in this disclosure. In some examples, the deck design parameters 145 can include a joist span parameter 145A, a joist size parameter 145B, a joist quantity parameter 145C, a joist cantilever length parameter 145D, a joist board length parameter 145E, a beam span parameter 145F, a beam size parameter 145G, a beam quantity parameter 145H, a beam cantilever length parameter 145I, a beam board length parameter 145J, a post size parameter 145K, a post quantity parameter 145L, and/or a post board length parameter 145M. The programming logic executed by the deck frame design engine 140 can incorporate any or all of the rules or specifications outlined in Table 1 and Table 2 (included above).

In many embodiments, the deck frame design engine 140 generates a robust support framework while also executing material optimization logic that minimizes material usage, thereby maintaining structural integrity and avoiding unnecessary over-engineering. In some examples, the deck frame design engine 140 performs material optimization by iteratively evaluating multiple compliant configurations to reduce total member counts, board lengths, or ply requirements while maintaining or exceeding code-mandated safety factors. As described in other portions of this disclosure, it can be important to avoid over-engineering not only to reduce material costs, but also to avoid placing unnecessary stress on the dwelling or foundation where the deck structure is being installed. Thus, the programming logic of the deck frame design engine 140 is configured to balance these two competing interests to output an optimized deck framing plan.

In certain embodiments, the deck frame design engine 140 can further determine component positioning and layout, including joist spacing centerlines, beam line locations, post grid coordinates, splice locations for multi-span beams, and cantilever extents, thereby producing a complete framing plan suitable for downstream visualization, bill-of-materials generation, and permitting documentation.

In step 503, a second GUI 170B can optionally be presented to the end-user, which displays some or all of the deck frame design parameters 145 and/or other determinations made by the deck frame design engine 140. The second GUI 170B can enable the end-user to review and approve the deck frame design parameters 145 for further processing. If changes are desired, an option may be presented that enables the end-user to return to the first GUI 170A (step 504) and re-enter or revise the specification parameters 130 for the deck framing plan.

In some embodiments, the deck frame design engine 140 can present the end-user with multiple deck frame design plan options, thereby permitting the user to choose between different options for constructing the deck and support structures. Each option is computed to satisfy applicable code requirements, but the alternatives can reflect distinct tradeoffs—for example, design configurations that minimize material counts versus design configurations that introduce additional posts, reduced spans, and/or increased member sizes to enhance stiffness and redundancy. By surfacing these code-compliant variants, the deck frame design engine 140 enables the end-user to select the most appropriate solution for the intended application and expected loads, such as lighter-duty residential use, higher-occupancy commercial settings, or industrial installations with elevated load demands.

The discussion below with reference to FIGS. 7B and 7C illustrates an example in which the deck frame design engine 140 generated two different design plan options. Both of these design plans were generated by the above-described background processing operations of the deck design engine 140 based on the specification parameters 130 illustrated in FIG. 7A:
a. Deck Length: 10 feet
b. Deck Width: 10 feet
c. Deck Height: 3 feet
d. Joist Spacing: 12 inches
e. Cantilever: Enabled
f. Include 2×12 Joists: Enabled

FIG. 7B is an example of the second GUI 170B that may be utilized to display deck frame design parameters 145 determined by the deck design engine 140 in accordance with a first design option. This first design option corresponds to a compliant structure design that minimizes material counts.

In this example, the second GUI 170B displays a first table that identifies deck component and dimension information, including the types of materials (joists and beams), the quantities of each material, span details, and cantilever information. A second table includes a total material list that was assembled by the deck design engine 140, indicating the full list of material components (posts, joists, and beams), size and dimension information for each component, the length of each component, and the quantity of each component.

Based on the input specification parameters 130, the programming logic of the deck design engine 140 executed a series of calculations to determine a first design option with the deck frame design parameters 145 that are optimized for both code-compliance and material usage as follows:
a. Joist Span: 6 feet
b. Joist Size: 2×6
c. Number of Joists: 11
d. Joist Cantilever Length: 2 feet
e. Beam Span: 6 feet
f. Beam Size: 2-2×6
g. Number of Beams: 2
h. Beam Cantilever Length: 2 feet
i. Post Size: 4×4
j. Number of Posts: 4

FIG. 7C illustrates a second design option that was generated by the programming logic of the deck design engine 140 based on these input specification parameters 130 shown in FIG. 7A. This second design option provides increased structural integrity (with a greater number of materials) and is able to support greater loads. With this second design option, the deck frame design parameters 145 were computed as follows:
a. Joist Span: 6 feet
b. Joist Size: 2×6
c. Number of Joists: 11
d. Joist Cantilever Length: 2 feet
e. Beam Span: 3 feet
f. Beam Size: 2-2×6
g. Number of Beams: 2
h. Beam Cantilever Length: 2 feet
i. Post Size: 4×4
j. Number of Posts: 6
k. Total Material Units: 21

Relative to the first design option, the deck frame design parameters 145 incorporate additional integrity-enforcing components (an additional two posts with a reduced beam span), which can be useful if the deck structure is intended to support heavier loads.

While the illustrative example above describes two alternative design options, the deck frame design engine 140 can compute numerous options across a broader solution space. Each option can be generated to be compliant with applicable building code specifications and can represent a tradeoff between material usage and enhanced structural performance. By programmatically enumerating and evaluating these code-compliant alternatives against the input specification parameters 130 and internal optimization criteria, the deck design engine 140 enables the selection of a configuration best suited to the anticipated use case and operating conditions, including expected loads, permissible deflection targets, budget constraints, and/or whether the installation is residential, commercial, or industrial in nature.

In certain embodiments, the second GUI 170B can include an option that enables the end-user to submit a request to generate a 3D deck frame visualization 165 corresponding to a desired design option (in the above example, corresponding to the first design option and/or second design option).

In step 505, a model generation request is transmitted to the 3D modeling engine 160 to generate a 3D deck frame visualization 165 corresponding to a selected design option. The model generation request may include the deck frame design parameters 145 corresponding to the selected design option and/or may prompt the 3D modeling engine 160 to access or retrieve the deck frame design parameters 145 from a database associated with the deck design application 150. Upon receiving the request, the 3D modeling engine 160 may automatically generate the 3D deck frame visualization 165 based on the corresponding deck frame design parameters 145.

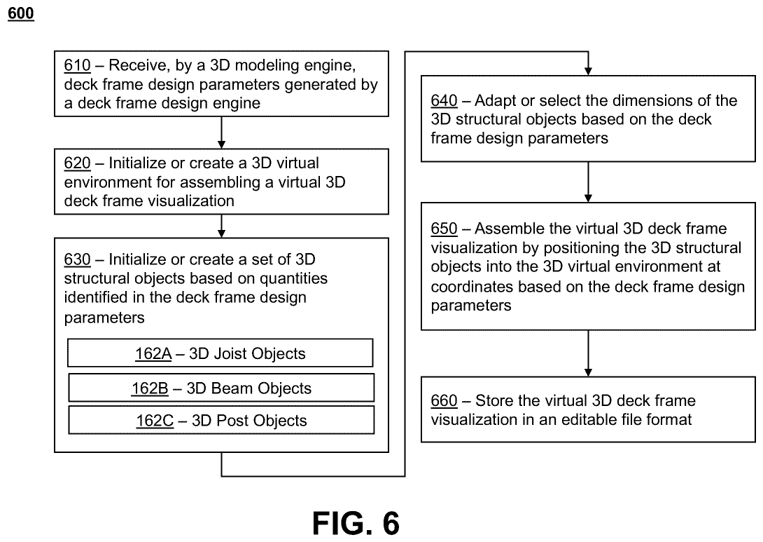

FIG. 6, which is described further below, illustrates one exemplary process flow that may be executed by the 3D modeling engine 160 to generate the 3D deck frame visualization 165. Other appropriate techniques also can be employed.

In certain embodiments, the 3D modeling engine 160 can generate or create the 3D deck frame visualization 165 by creating or adapting a plurality of 3D structural objects 162 to align with the deck frame design parameters 145, and assembling the plurality of 3D structural objects 162 at specified positions within a 3D virtual environment 161.

The 3D modeling engine 160 can be configured with generative capabilities that enable the 3D modeling engine to receive or ingest data and/or parameters (e.g., deck frame design parameters 145) and utilize the parameters or data to generate, modify, and/or create a 3D virtual environment and/or content included in the 3D virtual environment (e.g., content including the virtual scene, deck structure model, etc.). The 3D engine can generate the content using various types of generative functionalities and capabilities.

The 3D modeling engine 160 may generate or initialize the 3D virtual environment 161 in response to receiving the model generation request. The 3D virtual environment 161 may comprise a virtual scene or setting in three-dimensional virtual space. The 3D virtual environment 161 and/or corresponding three-dimensional space may be defined using a Cartesian coordinate system that comprises three axes (e.g., the x-axis, y-axis, and z-axis), and various types of 3D structural objects 162 can be inserted at locations defined by 3D reference points within the three-dimensional space, allowing for precise placement and/or manipulation of the 3D structural objects 162 in the virtual space.

Exemplary 3D structural objects 162 inserted into the virtual scene within the 3D virtual environment 161 can include joist objects, beam objects, post objects, platform board or surface objects, hardware connector objects, and/or other objects corresponding to structural components of a deck structure or support framework. In some embodiments, the 3D structural objects 162 inserted into the virtual scene also may correspond to decking platform structures, decking board structures, railing structures, stairway structures, housing connection structures, and/or any other structure that may be incorporated into or attached to a deck structure.

In some embodiments, the 3D modeling engine 160 can include or access a database that includes configurable, pre-assembled objects corresponding to some or all of the 3D structural objects 162 mentioned above, and the 3D modeling engine 160 can adapt the sizes, dimensions, and/or configurations of the objects to align with or match the sizes, dimensions, and/or configurations specified by the deck frame design parameters 145 for the deck structure being assembled. Additionally, in some examples, the 3D modeling engine can replicate the 3D objects corresponding to deck structure components based on the quantities specified in the deck design parameters (e.g., based on the quantities specified in the joist quantity parameter 145C, beam quantity parameter 145H, post quantity parameter 145L, etc.) and adapt the dimensions or appearance of each object as needed to conform with the deck frame design parameters 145. In this manner, a 3D structural object 162 can be inserted into the 3D virtual environment 161 for each component identified in a material listing included in the deck design results produced by the deck design engine 140.

Alternatively, or additionally, upon receiving a new request to generate a 3D deck frame visualization, the 3D modeling engine 160 can initialize or generate new 3D structural objects 162 (e.g., objects corresponding to joint structures, beam structures, post structures, etc.) based on the quantities specified in the deck frame design parameters 145 and dynamically customize each object such that the sizes, dimensions, and/or configurations of the object align with or match the deck frame design parameters 145. Thus, a separate 3D structural object 162 can be newly created and customized for each component identified in a material listing included in the deck frame design parameters 145.

The 3D modeling engine can be configured to assemble the 3D structural objects within the 3D virtual environment to create a 3D model corresponding to the 3D deck frame visualization 165. This can involve determining the positions or locations of the 3D structural objects 162 in the 3D virtual environment 161 and/or determining spacings between or among the 3D structural objects 162 within the 3D virtual environment 161.

In certain embodiments, the 3D modeling engine 160 determines the precise placement coordinates for each object within the three-dimensional Cartesian system based on the deck frame design parameters 145 and/or based on prestored engineering or deck design rules. For example, joist centerlines can be derived from the joist spacing parameter 145C and projected along an axis corresponding to deck length, beam lines can be positioned at calculated offsets from the deck perimeter or joist ends according to the beam span parameter 145F and cantilever limits, and post locations can be assigned to a grid of X-Y coordinates at beam intersections or specified support points with Z coordinates determined by deck height and footing elevations. The engine can further calculate clearances, alignments, and end conditions (e.g., hanger seats, bearing lengths, rim connections) and propagate these constraints into object transforms so that each object is translated, rotated, and scaled to match the specified dimensions and orientation. Using these computed transforms, the 3D modeling engine places and instantiates all required objects—joists, beams, posts, blocking, rim members, and, in some cases, connectors and decking—at their respective coordinates, thereby producing the 3D deck frame visualization 165 that accurately reflects the framing plan and enables interactive inspection from multiple viewpoints.

In certain embodiments, the 3D deck frame visualization 165 can be stored and/or exported in various file formats to facilitate review, collaboration, and downstream use. Exemplary formats can include glTF/glb, OBJ, MTL, STL, FBX, and/or DAE formats. In some cases, the visualization 165 also can be provided as a packaged scene or viewer file suitable for browser-based viewing, and as 2D derivations such as SVG or PDF snapshots for permitting documentation and material takeoff references.

In certain embodiments, a rendering component of the 3D modeling engine 160 can be configured to convert the assembled 3D deck model of the 3D deck frame visualization 165 into 2D and 3D visual outputs, including still images, animated sequences, and/or interactive views. The rendering component can employ rendering techniques to evaluate scene lighting, material reflectance, and surface textures, and can compute shadows, ambient occlusion, specular highlights, and transparency to produce photorealistic results, while also supporting stylized modes for simplified technical illustration. In some embodiments, the rendering component can generate orthographic and perspective views, section cuts, exploded assemblies, and dimensioned callouts, and may overlay annotations, part identifiers, and bill-of-material cues for permitting and procurement packages.

The 3D modeling engine 160 can be implemented in various programming languages (e.g., Python, JavaScript, PHP, etc.). In some embodiments, the backend framework of the deck design application 150 can be implemented in Python, and the 3D modeling engine 160 may incorporate the Three.js JavaScript library to implement some or all of the 3D modeling functionalities described herein.

In step 506, the 3D deck frame visualization 165 generated by the 3D modeling engine 160 can be presented or displayed to the end-user via a third GUI 170C. In certain embodiments, the third GUI 170C can provide interactive controls that allow the end-user to view the visualization 165 from multiple perspectives, including orbit, pan, and zoom operations, as well as selectable orthographic and perspective camera modes for top, side, and isometric views.

In certain embodiments, the third GUI 170C also may incorporate a 3D model editing environment configured to enable the end-user to make adjustments to the 3D deck frame visualization 165, such as modifying member sizes, updating joist spacing, toggling cantilever features, repositioning posts or beams within permitted constraints, and regenerating the model to reflect revised specification parameters 130 or updated deck frame design parameters 145. In some examples, edits made through the 3D model editor can be validated against code-compliance rules and, upon approval, persisted to the deck design results 180 and any associated export files.

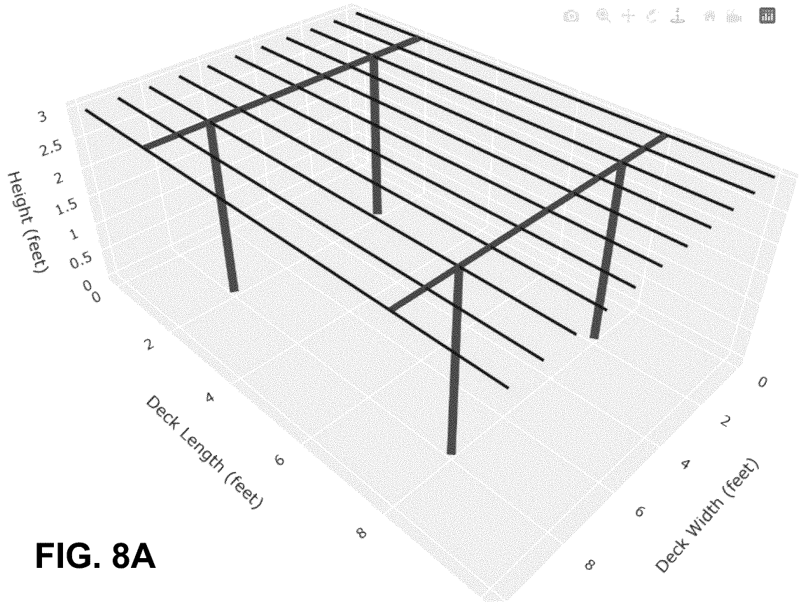

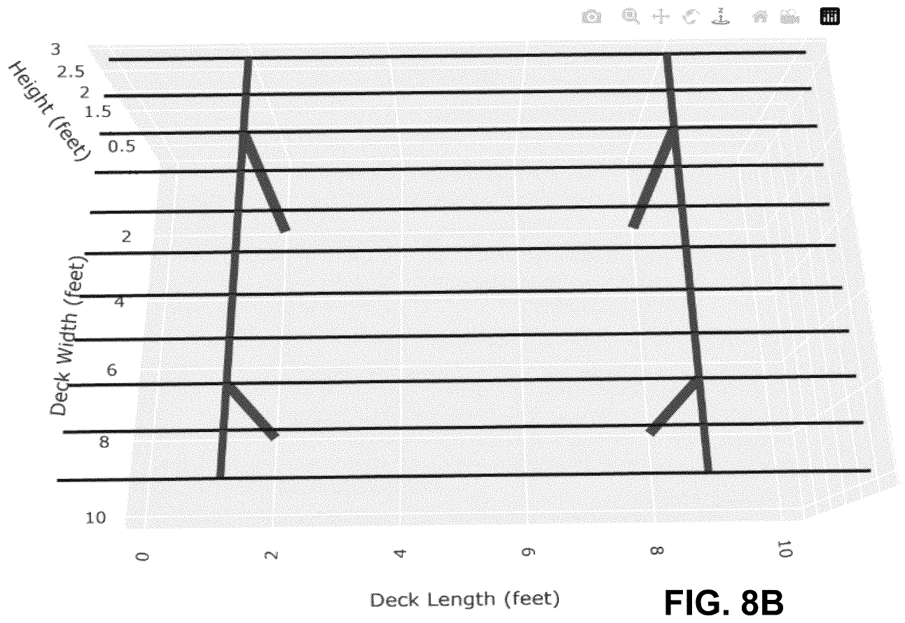

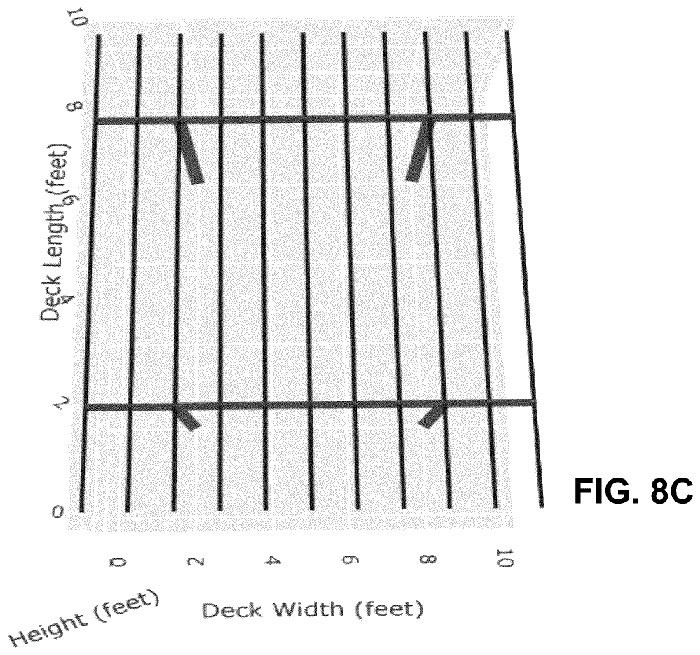

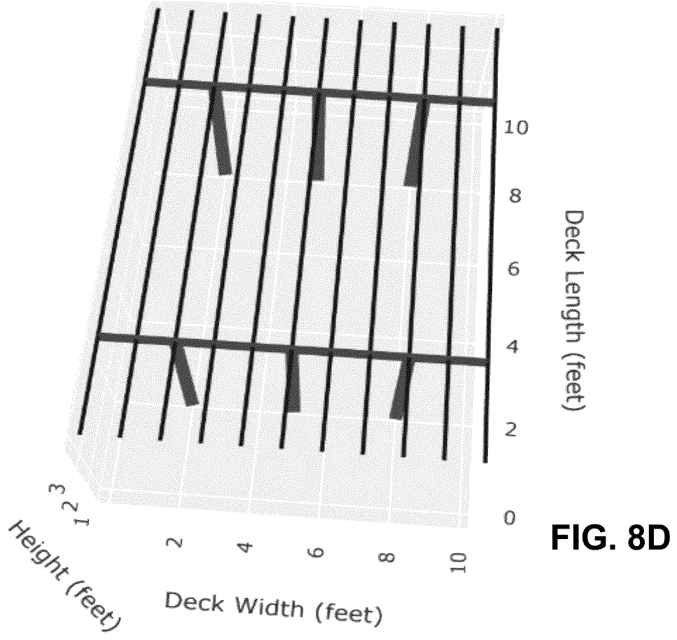

FIGS. 8A-8D illustrate two exemplary 3D deck frame visualizations 165 that were generated by this 3D modeling engine 160. Specifically, FIGS. 8A, 8B, and 8C illustrate a 3D deck frame visualization 165 that was generated based on the first design option described above (i.e., based on the deck design parameters 145 illustrated in FIG. 7B), and FIG. 8D illustrates another 3D deck frame visualization 165 that was generated based on the second design option described above (i.e., based on the deck frame design parameters 145 illustrated in FIG. 7C).

In steps 507A and 507B, all of the data associated with the deck frame plan can be stored and/or packaged into a set of deck design results 180 for the end-user. This may include the deck frame design parameters 145 and/or any other data that is generated by the deck frame design engine 140 (step 507A), as well as the 3D deck frame visualization 165 and/or other visualization data (e.g., 2D images) generated by the 3D modeling engine 160. In some embodiments, the deck design results 180 may be stored in a database of the deck design application 150 and associated with the user account of the end-user.

In step 509, the end-user is provided access to the deck design results 180 and may view, download, or share the deck design results 180 using the computing device 110. In some exemplary scenarios, the end-user may utilize the deck design results 180 to procure materials and generate purchase orders, submit permit applications with supporting plans and visualizations, guide on-site construction and assembly according to the framing plan, collaborate with inspectors or engineers for compliance review, and/or archive documentation for maintenance, future modifications, or inspections.

FIG. 6 illustrates a flow chart for an exemplary method 600 for generating a 3D deck frame visualization 165 according to certain embodiments. Method 600 is merely exemplary and is not limited to the embodiments presented herein. Method 600 can be employed in many different embodiments or examples not specifically depicted or described herein. In some embodiments, the steps of method 600 can be performed in the order presented. In other embodiments, the steps of method 600 can be performed in any suitable order. In still other embodiments, one or more of the steps of method 600 can be combined or skipped. In many embodiments, system 100, deck design application 150, and/or 3D modeling engine 160 can be configured to perform method 600 and/or one or more of the steps of method 600. In these or other embodiments, one or more of the steps of method 600 can be implemented as one or more computer instructions configured to run at one or more processing devices 102 and configured to be stored at one or more non-transitory computer storage devices 101. Such non-transitory memory storage devices 101 can be part of a computer system such as computing device 110 and/or server 120.

In step 610, a plurality of deck frame design parameters 145 generated by a deck frame design engine 140 are received by a 3D modeling engine 160. The deck frame design parameters 145 may include any of those described above with reference to FIG. 4 and/or other types of deck frame design parameters 145.

In step 620, a 3D virtual environment 161 for assembling a virtual 3D deck frame visualization 165 is initialized or created. The 3D virtual environment 161 may include a three-dimensional space that is defined using a Cartesian coordinate system that comprises three axes (e.g., the x-axis, y-axis, and z-axis).

In step 630, a plurality of 3D structural objects 162 are initialized or created based on quantities identified in the deck frame design parameters 145. In some examples, the 3D modeling engine 160 may initialize or create a first set of 3D joist objects 162A based on the quantities specified in the joist quantity parameter 145C, a second set of 3D beam objects 162B based on the beam quantity parameter 145H, and a third set of 3D post objects 163C based on the post quantity parameter 145L. Other 3D objects also can be created for other types of structural components mentioned in this disclosure.

In step 640, the dimensions of the 3D structural objects may be adapted or selected based on the deck frame design parameters 145. In some examples, the 3D modeling engine 160 may scale, configure, or select a first set of 3D joist objects according to the joist size parameter 145B and joist board length parameter 145E; a second set of 3D beam objects according to the beam size parameter 145G and beam board length parameter 145J; and a third set of 3D post objects according to the post size parameter 145K and post board length parameter 145M. Other dimensional adjustments also may be applied to additional 3D objects corresponding to other structural components mentioned in this disclosure.

In step 650, the virtual 3D deck frame visualization 165 is generated or assembled by adding or inserting the 3D structural objects 162 into the 3D virtual environment 161 and positioning the 3D structural objects 162 into the 3D virtual environment at coordinates based on the deck frame design parameters 145. In some examples, the 3D modeling engine 160 may place a first set of 3D joist objects along calculated centerlines derived from the joist spacing parameter 145D, with endpoints and overhangs constrained by the joist span parameter 145A and joist cantilever length parameter 145D; a second set of 3D beam objects at offsets determined by the beam span parameter 145F and beam cantilever length parameter 145I, aligned beneath joist bearing locations or hanger seats; and a third set of 3D post objects at grid intersections defined by beam line locations and deck perimeter references, with Z-axis positions set according to deck height and footing elevations. Other placement operations also may be performed for additional 3D objects corresponding to other structural components mentioned in this disclosure, including rim members, blocking, and connectors, with clearances, alignments, and end conditions applied to ensure a code-compliant assembly.

In step 660, the virtual 3D deck frame visualization 165 is stored in an editable file format. The virtual 3D deck frame visualization 165 may be associated with a deck design plan that was created via the deck design application 150 and/or a user account of an end-user that created or initiated the deck design plan.

As evidenced by the disclosure herein, the inventive techniques set forth in this disclosure are rooted in computer technologies that overcome existing problems in known engineering, architectural, and design systems, including problems dealing with manual structural calculations, inconsistent code interpretation, inefficient plan drafting, and error-prone visualization workflows. The techniques described in this disclosure provide a technical solution (e.g., one that utilizes programmatic plan computation, code-driven rule enforcement, optimization algorithms, and automated 3D model generation) for overcoming the limitations associated with known techniques. This technology-based solution marks an improvement over existing capabilities and functionalities related to deck design and modeling by improving the accuracy, speed, and reliability of code-compliant framing plans and the clarity and utility of associated visualizations and documentation.

The systems, applications, and functionalities described in this disclosure integrated several technical improvements and technology-based solutions.

In one example, the integration of the deck frame design engine 140 with the 3D modeling engine 160 provides a computer-centric improvement that eliminates the disconnect between computational plan generation and visualization workflows. Traditionally, framing calculations are performed manually and then manually reinterpreted in a separate drafting program, introducing transcription errors, dimensional mismatches, and significant latency. By linking the 3D modeling engine to the structured parameter outputs generated by the deck frame design engine, the computed spans, sizes, quantities, dimensions, and layouts can be programmatically propagated into a 3D virtual environment, where objects are instantiated, scaled, and positioned at precise Cartesian coordinates derived from the engineering or design outputs. This tight integration yields deterministic, repeatable model generation, reduces human error, and accelerates turnaround from inputs to deliverables within a single environment. As a result, the platform overcomes the technical problem of fragmented, error-prone design pipelines by providing an end-to-end, automated system that improves accuracy, performance, and usability for permitting, procurement, and construction.

In another example, the technique for automatically generating 3D deck frame visualizations provides a technical improvement by transforming structured design parameters into an instantiated, constraint-aware model without manual drafting. Conventional visualization workflows require repetitive, hand-built CAD operations that are slow, prone to dimensional drift, and difficult to keep synchronized with evolving engineering inputs, leading to inconsistent drawings and delayed iteration cycles. By programmatically deriving object geometries, transforms, and placements from computed spans, sizes, quantities, and layout constraints, the 3D modeling engine produces deterministic and reproducible models that reflect code-driven rules, with automated recalculation and regeneration upon input changes. This eliminates transcription and alignment errors, enables real-time validation of clearances and bearing conditions, and accelerates the creation of permit-ready views and export files. Additionally, the automated 3D modeling techniques support interactive perspective and orthographic inspections, and streamlines downstream deliverables, thereby overcoming the technical problems of manual, fragmented, and error-prone visualization pipelines.

In a further example, when viewed as a whole, the overall process of assembling a deck framing plan comprises a sequenced series of interconnected steps (e.g., user-specified parameter collection, automated derivation of design parameters based on user-specified parameters, 3D model generation based on design parameters, and packaging of comprehensive results based outputs from both the design engine and 3D modeling engine) constitutes a computer-centric workflow that provides a technical improvement over disconnected design tools and manual engineering practices. By capturing a small set of specification parameters (e.g. in some cases, only six parameters) through a GUI or API, computing code-constrained framing plans in the deck frame design engine, propagating those parameters directly into the 3D modeling engine for deterministic model instantiation, and then outputting synchronized deliverables that include engineering specifications, interactive visualizations, and export files, the system enforces a single source of truth across all stages. This end-to-end pipeline solves the technical problems of version drift, lossy data handoffs, and non-deterministic redraws that arise when calculations and drawings are performed in separate environments. It can improve latency and throughput by eliminating redundant manual steps, enhance data integrity through automatic regeneration upon input changes, and increase reliability by ensuring that bills of materials, annotated views, and compliance documentation remain consistent with the latest computed parameters. As a result, the process reduces iteration cycles, mitigates approval delays tied to inconsistent documentation, and scales efficiently for residential, commercial, and industrial scenarios via repeatable, auditable, and programmatically verifiable outputs.

In certain embodiments, a computerized method is disclosed that is implemented via computing instructions stored on one or more non-transitory storage devices and executed by one or more processing devices. The computerized method can comprise one or more of the following steps: (a) receiving, by a deck design application, specification parameters associated with a deck structure from an end-user; (b) generating, by a deck frame design engine of the deck design application, deck frame design parameters corresponding to a support framework for the deck structure based, at least in part, on the specification parameters; (c) receiving, by a three-dimensional (3D) modeling engine of the deck design application, the deck frame design parameters generated by the deck frame design engine; (d) generating, by the 3D modeling engine of the deck design application, a 3D deck frame visualization of the support framework for the deck structure based, at least in part, on the deck frame design parameters, wherein the 3D deck frame visualization is assembled in a 3D virtual environment using a plurality of 3D structural objects and the 3D modeling engine utilizes the deck frame design parameters generated by the deck frame design engine to determine dimensions of the plurality of 3D structural objects and coordinates for positioning the plurality of 3D structural objects within the 3D virtual environment; and (e) providing, by the deck design application, deck design results comprising the deck frame design parameters generated by the deck frame design engine and the 3D deck frame visualization generated by the 3D modeling engine to the end-user.

In certain embodiments, a system comprises: one or more processing devices, and one or more non-transitory storage devices for storing instructions. Execution of the instructions by the one or more processing devices causes the one or more processing devices to perform one or more of the following functions: (a) receiving, by a deck design application, specification parameters associated with a deck structure from an end-user; (b) generating, by a deck frame design engine of the deck design application, deck frame design parameters corresponding to a support framework for the deck structure based, at least in part, on the specification parameters; (c) receiving, by a three-dimensional (3D) modeling engine of the deck design application, the deck frame design parameters generated by the deck frame design engine; (d) generating, by the 3D modeling engine of the deck design application, a 3D deck frame visualization of the support framework for the deck structure based, at least in part, on the deck frame design parameters, wherein the 3D deck frame visualization is assembled in a 3D virtual environment using a plurality of 3D structural objects and the 3D modeling engine utilizes the deck frame design parameters generated by the deck frame design engine to determine dimensions of the plurality of 3D structural objects and coordinates for positioning the plurality of 3D structural objects within the 3D virtual environment; and (e) providing, by the deck design application, deck design results comprising the deck frame design parameters generated by the deck frame design engine and the 3D deck frame visualization generated by the 3D modeling engine to the end-user.

In certain embodiments, a computerized method is implemented via computing instructions stored on one or more non-transitory storage devices and executed by one or more processing devices. The computerized method comprises one or more of the following steps: (a) receiving, by a deck design application, specification parameters associated with a deck structure; (b) generating, by a deck frame design engine of the deck design application, deck frame design parameters corresponding to a support framework for the deck structure based, at least in part, on the specification parameters; (c) receiving, by a three-dimensional (3D) modeling engine of the deck design application, the deck frame design parameters generated by the deck frame design engine; (d) generating, by the 3D modeling engine of the deck design application, a 3D deck frame visualization of the support framework for the deck structure based, at least in part, on the deck frame design parameters, wherein the 3D deck frame visualization is assembled or generated in a 3D virtual environment using a plurality of 3D structural objects and the 3D modeling engine utilizes the deck frame design parameters generated by the deck frame design engine to customize dimensions and/or positioning of the plurality of 3D structural objects within the 3D virtual environment; and (e) providing access, by the deck design application, to the deck frame design parameters generated by the deck frame design engine and the 3D deck frame visualization generated by the 3D modeling engine.

In certain embodiments, a 3D modeling engine can include functionality to create or initialize a first set of 3D joist objects based on a first quantity parameter specified in deck frame design parameters generated by a deck frame design engine, to create or initialize a second set of 3D beam objects based on a second quantity parameter specified in those deck frame design parameters, and to create or initialize a third set of 3D post objects based on a third quantity parameter specified in the same deck frame design parameters, and may be configured to insert the first set of 3D joist objects, the second set of 3D beam objects, and the third set of 3D post objects into a 3D virtual environment.

In certain embodiments, the 3D virtual environment may be defined using a Cartesian coordinate system that comprises three axes, and the 3D modeling engine can be configured to determine coordinates or positions of the first set of 3D joist objects, the second set of 3D beam objects, and the third set of 3D post objects in the 3D virtual environment based, at least in part, on the deck frame design parameters.

In certain embodiments, the 3D modeling engine can customize dimensions of the first set of 3D joist objects by scaling, configuring, or selecting the first set of 3D joist objects according to a joist size parameter and/or a joist board length parameter specified in the deck frame design parameters generated by the deck frame design engine, can customize dimensions of the second set of 3D beam objects by scaling, configuring, or selecting the second set of 3D beam objects according to a beam size parameter and/or a beam board length parameter specified in the deck frame design parameters, and can customize dimensions of the third set of 3D post objects by scaling, configuring, or selecting the third set of 3D post objects according to a post size parameter and/or a post board length parameter specified in the deck frame design parameters.

In certain embodiments, the 3D deck frame visualization may be configured to at least visualize a proposed design of the support framework and depict the placement, sizing, and spacing of structural components of the support framework based, at least in part, on the deck frame design parameters.

In certain embodiments, the deck frame design engine can execute programming logic that computes structural requirements for the support framework based on specification parameters, selects structural components in accordance with applicable design constraints, determines quantities and dimensions for the selected structural components, generates a material listing, and generates deck frame design parameters indicative of component sizes, quantities, lengths, and/or spans.

In certain embodiments, the deck frame design engine may execute programming logic that performs code-compliance validation checks against one or more building code specifications to help ensure that the deck frame design parameters are compliant with the one or more building code specifications.

In certain embodiments, the deck frame design engine can utilize the specification parameters to generate at least two of a joist span parameter, a joist size parameter, a joist quantity parameter, a joist cantilever length parameter, and a joist board length parameter; at least two of a beam span parameter, a beam size parameter, a beam quantity parameter, a beam cantilever length parameter, and a beam board length parameter; and at least two of a post size parameter, a post quantity parameter, and a post board length parameter.

In certain embodiments, the deck frame design engine may be configured to generate a plurality of alternative, code-compliant design options for the support framework, where each option can represent distinct tradeoffs between minimizing construction materials and increasing structural integrity of the support framework.

In certain embodiments, the specification parameters can include a deck length parameter, a deck width parameter, a deck height parameter, a joist spacing parameter, a cantilever selection parameter, and a joist size allowance parameter.

In certain embodiments, a computer-implemented method for generating a code-compliant deck frame design is disclosed. The method comprises: (a) receiving, by a deck design application executed on one or more computing devices, a set of specification parameters comprising at least a deck length parameter, a deck width parameter, a deck height parameter, a joist spacing parameter, a cantilever selection parameter, and a joist size allowance parameter; (b) processing, by a deck frame design engine, the specification parameters to automatically determine a plurality of deck frame design parameters that comply with predetermined building-code rules, the deck frame design parameters comprising at least a joist span parameter, a joist size parameter, a joist quantity parameter, a joist cantilever length parameter, a beam span parameter, a beam size parameter, a beam quantity parameter, a beam cantilever length parameter, a post size parameter, a post quantity parameter, and corresponding board length parameters; (c) generating, by the deck frame design engine, at least one deck frame design option using the deck frame design parameters; (d) transmitting the deck frame design parameters to a 3D modeling engine; (e) instantiating, by the 3D modeling engine, a set of 3D structural objects comprising joist objects, beam objects, and post objects; (f) sizing, by the 3D modeling engine, the 3D structural objects based on the deck frame design parameters; (g) positioning, by the 3D modeling engine, the 3D structural objects within a 3D virtual environment at coordinates determined from the deck frame design parameters to generate a virtual 3D deck frame visualization; and (h) outputting, for display on a graphical user interface, the deck frame design parameters, the at least one deck frame design option, and the virtual 3D deck frame visualization.

In certain embodiments, a system for generating a code-compliant deck frame design is disclosed. The system comprises: one or more processors; and one or more memory devices storing instructions that, when executed by the processors, cause the system to: (a) receive a set of specification parameters defining characteristics of a deck structure; (b) apply a plurality of building-code rules to the specification parameters to automatically compute a set of deck frame design parameters; (c) generate one or more deck frame design options based on the deck frame design parameters; (d) provide the deck frame design parameters to a 3D modeling engine; (e) create, by the 3D modeling engine, 3D structural objects representing joists, beams, and posts; (f) automatically size and position the 3D structural objects within a 3D virtual environment according to the deck frame design parameters; and (g) display, via a graphical user interface, the deck frame design options and the corresponding 3D virtual deck frame visualization.

In certain embodiments, a non-transitory computer-readable medium is disclosed. The medium can store instructions that, when executed by one or more processors, cause a computing system to: (a) receive specification parameters defining a deck geometry and allowable framing characteristics; (b) determine, using a deck frame design engine, deck frame design parameters that satisfy predetermined structural and building-code constraints; (c) generate at least one deck frame design option based on the deck frame design parameters; (d) instantiate and dimension 3D structural objects representing joists, beams, and posts; (e) position the 3D structural objects within a virtual environment based on the deck frame design parameters; and (f) output a deck frame plan including the deck frame design parameters and a 3D deck frame visualization.

In certain embodiments, generating the deck frame design parameters comprises selecting a joist size from a lookup table based on a required span determined from the deck length parameter and joist spacing parameter.

In certain embodiments, the deck frame design engine determines a beam size based on a computed tributary area associated with the joists.

In certain embodiments, the method further comprises generating multiple deck frame design options having different material quantities or component dimensions.

In certain embodiments, the 3D modeling engine assigns global coordinates to the joist, beam, and post objects based on spacing and span parameters.

In certain embodiments, outputting the deck frame design parameters comprises generating a formatted material list including board lengths and counts.

In certain embodiments, the deck frame design engine validates all spans, cantilever distances, and component sizes according to predetermined code tables.

In certain embodiments, the 3D deck frame visualization is stored in an editable file format.

In certain embodiments, the memory further stores a building-code dataset comprising span limits used by the deck frame design engine.

In certain embodiments, a graphical user interface displays multiple design options for user selection.

In certain embodiments, the instructions further cause the system to detect invalid framing configurations and automatically adjust structural parameters in response to detecting the same.

In certain embodiments, generating the 3D visualization occurs in real time in response to updated specification parameters.

In certain embodiments, the 3D modeling engine computes board quantities by aggregating the dimensions of the 3D structural objects.

In certain embodiments, the deck frame design parameters include dimensions for decking boards.

In certain embodiments, determining the beam quantity comprises optimizing beam count to minimize material usage while maintaining code compliance.

In certain embodiments, the deck frame design engine automatically determines a number of posts required for each beam based on allowable spans.

In certain embodiments, the 3D modeling engine colors or labels each structural object based on its type or size.

In certain embodiments, generating the deck frame design parameters includes computing cantilever allowances based on user selection and code limits.

In certain embodiments, the specification parameters consist of no more than six numeric inputs provided by a user.

The exemplary embodiments of the deck design application described herein are provided as examples to demonstrate possible implementations, and should not be construed as limiting the scope of the invention. Numerous modifications, variations, and adaptations to the disclosed embodiments may be made without departing from the spirit and scope of the invention, including changes to the specific components, features, functionalities, and methods of operation described herein.

Embodiments may include a computer program product accessible from a computer-usable or computer-readable medium providing program code for use by or in connection with a computer or any instruction execution system. A computer-usable or computer-readable medium may include any apparatus that stores, communicates, propagates, or transports the program for use by or in connection with the instruction execution system, apparatus, or device. The medium can be a magnetic, optical, electronic, electromagnetic, infrared, or semiconductor system (or apparatus or device) or a propagation medium. The medium may include a computer-readable storage medium, such as a semiconductor or solid-state memory, magnetic tape, a removable computer diskette, a random access memory (RAM), a read-only memory (ROM), a rigid magnetic disk and an optical disk, etc.

A data processing system suitable for storing and/or executing program code may include at least one processor coupled directly or indirectly to memory elements through a system bus. The memory elements can include local memory employed during actual execution of the program code, bulk storage, and cache memories that provide temporary storage of at least some program code to reduce the number of times code is retrieved from bulk storage during execution. Input/output or I/O devices (including but not limited to keyboards, displays, pointing devices, etc.) may be coupled to the system either directly or through intervening I/O controllers.

Network adapters may also be coupled to the system to enable the data processing system to become coupled to other data processing systems or remote printers or storage devices through intervening private or public networks. Modems, cable modems, and Ethernet cards are just a few of the currently available types of network adapters.

It should be recognized that any features and/or functionalities described for an embodiment in this application can be incorporated into any other embodiment mentioned in this disclosure. Moreover, the embodiments described in this disclosure can be combined in various ways. Additionally, while the description herein may describe certain embodiments, features, or components as being implemented in software or hardware, it should be recognized that any embodiment, feature, or component that is described in the present application may be implemented in hardware, software, or a combination of the two.

While various novel features of the invention have been shown, described, and pointed out as applied to particular embodiments thereof, it should be understood that various omissions and substitutions, and changes in the form and details of the systems and methods described and illustrated, may be made by those skilled in the art without departing from the spirit of the invention. Amongst other things, the steps in the methods may be carried out in different orders in many cases where such may be appropriate. Those skilled in the art will recognize, based on the above disclosure and an understanding of the teachings of the invention, that the particular hardware and devices that are part of the system described herein, and the general functionality provided by and incorporated therein, may vary in different embodiments of the invention. Accordingly, the description of system components is for illustrative purposes to facilitate a full and complete understanding and appreciation of the various aspects and functionality of particular embodiments of the invention as realized in system and method embodiments thereof. Those skilled in the art will appreciate that the invention can be practiced in other than the described embodiments, which are presented for purposes of illustration and not limitation. Variations, modifications, and other implementations of what is described herein may occur to those of ordinary skill in the art without departing from the spirit and scope of the present invention and its claims.

1. A computerized method implemented via computing instructions stored on one or more non-transitory storage devices and executed by one or more processing devices, the computerized method comprising:
receiving, by a deck design application, specification parameters associated with a deck structure from an end-user;
generating, by a deck frame design engine of the deck design application, deck frame design parameters corresponding to a support framework for the deck structure based, at least in part, on the specification parameters;
receiving, by a three-dimensional (3D) modeling engine of the deck design application, the deck frame design parameters generated by the deck frame design engine;
generating, by the 3D modeling engine of the deck design application, a 3D deck frame visualization of the support framework for the deck structure based, at least in part, on the deck frame design parameters, wherein the 3D deck frame visualization is assembled in a 3D virtual environment using a plurality of 3D structural objects and the 3D modeling engine utilizes the deck frame design parameters generated by the deck frame design engine to determine dimensions of the plurality of 3D structural objects and coordinates for positioning the plurality of 3D structural objects within the 3D virtual environment; and
providing, by the deck design application, deck design results comprising the deck frame design parameters generated by the deck frame design engine and the 3D deck frame visualization generated by the 3D modeling engine to the end-user.

2. The computerized method of claim 1, wherein:
the 3D modeling engine creates or initializes a first set of 3D joist objects based on a first quantity parameter specified in the deck frame design parameters generated by the deck frame design engine;
the 3D modeling engine creates or initializes a second set of 3D beam objects based on a second quantity parameter specified in the deck frame design parameters generated by the deck frame design engine;
the 3D modeling engine creates or initializes a third set of 3D post objects based on a third quantity parameter specified in the deck frame design parameters generated by the deck frame design engine; and
the 3D modeling engine inserts the first set of 3D joist objects, the second set of 3D beam objects, and the third set of 3D post objects into the 3D virtual environment.

3. The computerized method of claim 2, wherein:
the 3D virtual environment is defined using a Cartesian coordinate system that comprises three axes; and
the 3D modeling engine determines coordinates or positions of the first set of 3D joist objects, the second set of 3D beam objects, and the third set of 3D post objects in the 3D virtual environment based, at least in part, on the deck frame design parameters.

4. The computerized method of claim 2, wherein:
the 3D modeling engine customizes the dimensions of the first set of 3D joist objects by scaling, configuring, or selecting the first set of 3D joist objects according to a joist size parameter and/or a joist board length parameter specified in the deck frame design parameters generated by the deck frame design engine;
the 3D modeling engine customizes the dimensions of the second set of 3D beam objects by scaling, configuring, or selecting the second set of 3D beam objects according to a beam size parameter and/or a beam board length parameter specified in the deck frame design parameters generated by the deck frame design engine; and
the 3D modeling engine customizes the dimensions of the third set of 3D post objects by scaling, configuring, or selecting the third set of 3D post objects according to a post size parameter and/or a post board length parameter specified in the deck frame design parameters generated by the deck frame design engine.

5. The computerized method of claim 1, wherein the 3D deck frame visualization at least visualizes a proposed design of the support framework and depicts a placement, sizing, and spacing of structural components of the support framework based, at least in part, on the deck frame design parameters.

6. The computerized method of claim 1, wherein the deck frame design engine executes programming logic that computes structural requirements for the support framework based on the specification parameters, selects structural components in accordance with applicable design constraints, determines quantities and dimensions for the selected structural components, generates a material listing, and generates the deck frame design parameters indicative of component sizes, quantities, lengths, and/or spans.

7. The computerized method of claim 1, wherein the deck frame design engine executes programming logic that performs code-compliance validation checks against one or more building code specifications to ensure the deck frame design parameters are compliant with the one or more building code specifications.

8. The computerized method of claim 1, wherein the deck frame design engine executes programming logic that utilizes the specification parameters to generate:
at least two of: a joist span parameter; a joist size parameter; a joist quantity parameter; a joist cantilever length parameter; and a joist board length parameter;
at least two of: a beam span parameter; a beam size parameter; a beam quantity parameter; a beam cantilever length parameter; and a beam board length parameter; and
at least two of: a post size parameter; a post quantity parameter; and a post board length parameter.

9. The computerized method of claim 1, wherein the deck frame design engine is configured to generate a plurality of alternative, code-compliant design options for the support framework, each option representing distinct tradeoffs between minimizing construction materials and increasing structural integrity of the support framework.

10. The computerized method of claim 1, wherein the specification parameters include:
a deck length parameter;
a deck width parameter;
a deck height parameter;
a joist spacing parameter;
a cantilever selection parameter; and
a joist size allowance parameter.

11. A system comprising:
one or more processing devices; and
one or more non-transitory storage devices for storing instructions, wherein execution of the instructions by the one or more processing devices causes the one or more processing devices to perform functions comprising:
receiving, by a deck design application, specification parameters associated with a deck structure from an end-user;
generating, by a deck frame design engine of the deck design application, deck frame design parameters corresponding to a support framework for the deck structure based, at least in part, on the specification parameters;
receiving, by a three-dimensional (3D) modeling engine of the deck design application, the deck frame design parameters generated by the deck frame design engine;
generating, by the 3D modeling engine of the deck design application, a 3D deck frame visualization of the support framework for the deck structure based, at least in part, on the deck frame design parameters, wherein the 3D deck frame visualization is assembled in a 3D virtual environment using a plurality of 3D structural objects and the 3D modeling engine utilizes the deck frame design parameters generated by the deck frame design engine to determine dimensions of the plurality of 3D structural objects and coordinates for positioning the plurality of 3D structural objects within the 3D virtual environment; and
providing, by the deck design application, deck design results comprising the deck frame design parameters generated by the deck frame design engine and the 3D deck frame visualization generated by the 3D modeling engine to the end-user.

12. The system of claim 11, wherein:
the 3D modeling engine creates or initializes a first set of 3D joist objects based on a first quantity parameter specified in the deck frame design parameters generated by the deck frame design engine;
the 3D modeling engine creates or initializes a second set of 3D beam objects based on a second quantity parameter specified in the deck frame design parameters generated by the deck frame design engine;
the 3D modeling engine creates or initializes a third set of 3D post objects based on a third quantity parameter specified in the deck frame design parameters generated by the deck frame design engine; and
the 3D modeling engine inserts the first set of 3D joist objects, the second set of 3D beam objects, and the third set of 3D post objects into the 3D virtual environment.

13. The system of claim 12, wherein:
the 3D virtual environment is defined using a Cartesian coordinate system that comprises three axes; and
the 3D modeling engine determines coordinates or positions of the first set of 3D joist objects, the second set of 3D beam objects, and the third set of 3D post objects in the 3D virtual environment based, at least in part, on the deck frame design parameters.

14. The system of claim 12, wherein:
the 3D modeling engine customizes the dimensions of the first set of 3D joist objects by scaling, configuring, or selecting the first set of 3D joist objects according to a joist size parameter and/or a joist board length parameter specified in the deck frame design parameters generated by the deck frame design engine;
the 3D modeling engine customizes the dimensions of the second set of 3D beam objects by scaling, configuring, or selecting the second set of 3D beam objects according to a beam size parameter and/or a beam board length parameter specified in the deck frame design parameters generated by the deck frame design engine; and
the 3D modeling engine customizes the dimensions of the third set of 3D post objects by scaling, configuring, or selecting the third set of 3D post objects according to a post size parameter and/or a post board length parameter specified in the deck frame design parameters generated by the deck frame design engine.

15. The system of claim 11, wherein the 3D deck frame visualization at least visualizes a proposed design of the support framework and depicts a placement, sizing, and spacing of structural components of the support framework based, at least in part, on the deck frame design parameters.

16. The system of claim 11, wherein the deck frame design engine executes programming logic that computes structural requirements for the support framework based on the specification parameters, selects structural components in accordance with applicable design constraints, determines quantities and dimensions for the selected structural components, generates a material listing, and generates the deck frame design parameters indicative of component sizes, quantities, lengths, and/or spans.

17. The system of claim 11, wherein the deck frame design engine executes programming logic that performs code-compliance validation checks against one or more building code specifications to ensure the deck frame design parameters are compliant with the one or more building code specifications.

18. The system of claim 11, wherein the deck frame design engine executes programming logic that utilizes the specification parameters to generate:
at least two of: a joist span parameter; a joist size parameter; a joist quantity parameter; a joist cantilever length parameter; and a joist board length parameter;
at least two of: a beam span parameter; a beam size parameter; a beam quantity parameter; a beam cantilever length parameter; and a beam board length parameter; and
at least two of: a post size parameter; a post quantity parameter; and a post board length parameter.

19. The system of claim 11, wherein the specification parameters include:
a deck length parameter;
a deck width parameter;
a deck height parameter;
a joist spacing parameter;
a cantilever selection parameter; and
a joist size allowance parameter.

20. A computerized method implemented via computing instructions stored on one or more non-transitory storage devices and executed by one or more processing devices, the computerized method comprising:
receiving, by a deck design application, specification parameters associated with a deck structure;
generating, by a deck frame design engine of the deck design application, deck frame design parameters corresponding to a support framework for the deck structure based, at least in part, on the specification parameters;
receiving, by a three-dimensional (3D) modeling engine of the deck design application, the deck frame design parameters generated by the deck frame design engine;
generating, by the 3D modeling engine of the deck design application, a 3D deck frame visualization of the support framework for the deck structure based, at least in part, on the deck frame design parameters, wherein the 3D deck frame visualization is assembled or generated in a 3D virtual environment using a plurality of 3D structural objects and the 3D modeling engine utilizes the deck frame design parameters generated by the deck frame design engine to customize dimensions and/or positioning of the plurality of 3D structural objects within the 3D virtual environment; and
providing access, by the deck design application, to the deck frame design parameters generated by the deck frame design engine and the 3D deck frame visualization generated by the 3D modeling engine.
